(19) United States
(12) Patent Application Publication
(10) Pub. No.: US 2008/0276032 A1
(43) Pub. Date: Nov. 6, 2008

(54) ARRANGEMENTS WHICH WRITE SAME DATA AS DATA STORED IN A FIRST CACHE MEMORY MODULE, TO A SECOND CACHE MEMORY MODULE

(76) Inventors: Junichi IIDA, Odawara (JP); Hiroki Kanai, Odawara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/132,243

(22) Filed: Jun. 3, 2008

Related U.S. Application Data
(63) Continuation of application No. 10/965,820, filed on Oct. 18, 2004.

(30) Foreign Application Priority Data
Aug. 27, 2004 (JP) 2004-249279

(51) Int. Cl. G06F 13/00; H03M 13/09

(52) U.S. Cl. 710/316; 714/758; 714/E11.042

(57) ABSTRACT

A storage device control apparatus including first and second systematic memory module groups, each of which is composed of a plurality of memory modules, a memory controller for controlling memory access to the memory modules belonging to each of the first systematic and second systematic memory module groups. When the memory controller detects failure in one of the other memory systems, the memory system performs memory access to the memory modules belonging to its own systematic memory module groups.

### CROSS REFERENCE TO RELATED APPLICATION

This is a continuation of U.S. application Ser. No. 10/965,820, filed Oct. 18, 2004. This application relates to and claims priority from Japanese Patent Application No. 2004-249279, filed on Aug. 27, 2004. The entirety of the contents and subject matter of all of the above is incorporated herein by reference.

### BACKGROUND OF THE INVENTION

The present invention relates in general to a storage device control apparatus, and, more particularly, to a storage device control apparatus for use in a memory system having a memory module connected to a memory controller by a serial interface to a storage device for storing information based upon access to the storage device control apparatus.

Recently, the amount of data typically processed by a computer system has been rapidly increasing. As a storage system for managing such data, a large scale storage system managed by a RAID (Redundant Arrays of Inexpensive Disks) method for providing a massive storage resource, called a mid-range class or an enterprise class, has been attracting attention. In order to efficiently use and manage such a massive data storage, a technique for connecting a storage system, such as a disk array device, to an information processing device by a SAN (Storage Area Network), to enable a massive access to the storage system at high speeds, has been developed. On the other hand, a NAS (Network Attached Storage) for connecting a storage system to an information processing device via a network using TCP/IP protocol and the like to accomplish access at the file level from the information process device also has been developed.

As a primary storage device of a storage system in which a high reliability is required, a registered DIMM (Dual In-line Memory Module) is used. In the registered DIMM, in order to ensure the reliability of the write data, an ECC memory for generating an ECC (Error Correcting Code) from the memory controller and storing the write data with the attached ECC in the registered DIMM is known. In the ECC memory, the ECC is read together with the write data during a read-access process, and, thus, a data error can be detected and corrected. Conventionally, parallel interface signal lines are connected between the memory controller and the memory module (for example, see Patent Document 1); and, although one of the parallel interface signal lines may be out of order, an error can be detected and corrected by the ECC. However, there is a limit to transmitting data at high speeds in a parallel interface, and it is difficult to mount the circuit components thereof due to a sharp increase in the wiring density. In addition, in a stub-type memory connection, a deterioration of the signals can be prevented from being generated due to multiple reflection of the signal from the stub bus, or due to a resistance component, a capacitance component and an inductance component of the stub bus.

In view of this technical background, recently, an attempt to realize a connection in which a serial interface is provided between the memory controller and the memory module to improve the data transfer speed is currently being investigated. For example, in a FB-DIMM (Fully-Buffered DIMM), the interface with the memory controller has a serial interface similar to a PCI express, and the memory controller can be connected to the FB-DIMM in a point-to-point manner, whereby the data can be transmitted at high speeds, while signal deterioration due to the effect of the stub bus is avoided and the circuit components can be easily mounted.

### [Patent Document 1]

Japanese unexamined Patent Publication No. 2001-222472

The FB-DIMM for a server is used as a storage device in the storage device control apparatus for receiving an input/output request from an information-processing device to the storage device and for processing the access thereof, whereby the process can be performed at high speeds and the circuit components can be easily mounted.

However, in the case of using a parallel transmitting method, an error can be corrected by the ECC even if one of the interface signal lines is out of order; however, in the case of using the serial transmitting method, the data cannot be transmitted if an obstacle is generated in the interface signal line. In the storage system in which a high reliability is needed, a sufficient fail-safe countermeasure must be prepared in advance against obstacles in the interface signal line.

### SUMMARY OF THE INVENTION

Accordingly, an object of the present invention is to provide a storage device control apparatus which serves as a storage device for temporarily storing data, while being capable of ensuring a sufficient reliability even when a memory controller and memory modules are connected by a serial interface.

In order to solve the above-mentioned problems, a storage device control apparatus according to the present comprises a channel control unit for outputting an I/O request for accessing a storage device in response to a data input/output request in a file unit received from an information processing device. The channel control unit includes a CPU for receiving the data input/output request in the file unit, an I/O processor for outputting the I/O request corresponding to the data input/output request in the file unit in response to an instruction from the CPU, and a memory system for temporarily storing information required for a file access process of the CPU and having a plurality of memory modules and a memory controller for controlling memory access to the plurality of memory modules. A command, an address and data are serially transmitted from the memory controller to each of the memory modules, each of the memory modules having a plurality of memory elements and a plurality of buffer units. Each of the buffer units receives and interprets the command serially transmitted from the memory controller, controls the memory access to each of the memory elements from the memory controller, and simultaneously converts the serially transmitted data into parallel data and transmits the parallel data to each of the memory elements. The memory modules and the memory controller are connected by duplicated serial interfaces.

Also, the above-mentioned memory system is not limited to a temporary storing device of the channel control unit for processing a file access request from the information-processing device, and various devices (a cache memory, a shared memory, and a temporary storing device of a disk control unit, etc.) can be applied.

The memory system comprises, for example, a plurality of memory modules and a memory controller for controlling memory access to the plurality of memory modules, and a command, an address and data are serially transmitted from the memory controller to each of the memory modules, each of the memory modules having a plurality of memory elements and a plurality of buffer units. Each of the buffer units receives and interprets the command serially transmitted from the memory controller, controls the memory access to each of the memory elements from the memory controller, and simultaneously converts the serially transmitted data into parallel data and transmits the parallel data to each of the memory elements. The memory modules and the memory controller are connected by duplicated serial interfaces.

Another configuration of the memory system comprises, for example, first systematic and second systematic memory-module groups, each composed of a plurality of memory modules, a memory controller for controlling memory access to the memory modules belonging to each of the first and second systematic memory-module groups, and a control circuit for controlling the switching of a memory access path from the memory controller to each memory module. A command, an address and data are serially transmitted from the memory controller to each of the memory modules, each of the memory modules having a plurality of memory elements and a plurality of buffer units. Each of the buffer units receives and interprets the command serially transmitted from the memory controller, controls the memory access to each of the memory elements from the memory controller, and simultaneously converts the serially transmitted data into parallel data and transmits the parallel data to each of the memory elements. The memory controller and each of the memory modules are connected to each other by a serial interface such that a first access path for performing a memory access from the memory controller to the memory module belonging to the first systematic memory module group and a second access path for performing a memory access from the memory controller to the memory module belonging to the second systematic memory module group are different from each other. The control circuit writes the same data as the data stored in the first systematic memory module through the first access path to the second systematic memory module through the second access path, when performing a write access from the memory controller to the first systematic memory module. Thereby, by dual writing of the data, the reliability of the memory system can be increased.

Another configuration of the memory system comprises, for example, a plurality of memory modules and a memory controller for controlling memory access to the plurality of memory modules, in which a command, an address and data are serially transmitted from the memory controller to each of the memory modules, each of the memory modules having a plurality of memory elements and a plurality of buffer units. Each of the buffer units receives and interprets the command serially transmitted from the memory controller, controls the memory access to each of the memory elements from the memory controller, and simultaneously converts the serially transmitted data into parallel data and transmits the parallel data to each of the memory elements. The memory controller comprises first and second memory interface units for loop-connecting with the buffer unit of each of the memory modules through a serial interface signal line. The memory controller can access each of the memory modules by any one of the first and second memory interface units. Thereby, by duplicating the access path such that the memory access can be performed in bi-directions of the loop-shaped serial interface, the reliability of the memory system can be increased.

Another configuration of the memory system comprises, for example, a plurality of the memory modules and a memory controller for controlling memory access to the plurality of memory modules, wherein a command, an address and data are serially transmitted from the memory controller to each of the memory modules, each of the memory modules having a plurality of memory elements and a plurality of buffer units. Each of the buffer units receives and interprets the command serially transmitted from the memory controller, controls the memory access to each of the memory elements from the memory controller, and simultaneously converts the serially transmitted data into parallel data and transmits the parallel data to each of the memory elements. The memory controller and the buffer unit of each of the memory modules are connected to each other through duplicated serial interface signal lines. Thereby, by duplicating the serial interface signal line serially connecting a memory controller and a memory module, the reliability of the memory system can be increased.

### BRIEF DESCRIPTION OF THE DRAWINGS

FIG. 1 is a block diagram which illustrates the structure of a storage system according to a present invention.

FIG. 2 is a block diagram which illustrates the detailed structure of a storage system according to the present invention.

FIG. 3 is a diagram which illustrates the structure of a disk control unit according to the present invention.

FIG. 4 is a diagram which illustrates the structure of a channel control unit according to the present invention.

FIG. 5 is a block diagram which illustrates the structure of a FB-DIMM according to the present invention.

FIG. 6 is a block diagram which illustrates the structure of a memory according to the present invention.

FIG. 7 is a diagram which illustrates the structure of another memory according to the present invention.

FIG. 8 is a block diagram which illustrates the structure of another memory according to the present invention.

FIG. 9 is a diagram which illustrates the structure of another memory according to the present invention.

FIG. 10 is a block diagram which illustrates the structure of another memory according to the present invention.

FIG. 11 is a diagram which illustrates the structure of another memory according to the present invention.

FIG. 12 is a diagram which illustrates the structure of another memory according to the present invention.

FIG. 13 is a diagram which illustrates the structure of another memory according to the present invention.

FIG. 14 is a diagram which illustrates the structure of another memory according to the present invention.

FIG. 15 is a diagram which illustrates the structure of another memory according to the present invention.

FIG. 16 is a diagram which illustrates the structure of another memory according to the present invention.

FIG. 17 is a diagram which illustrates the structure of another memory according to the present invention.

FIG. 18 is a diagram which illustrates the structure of another memory according to the present invention.

FIG. 19 is a diagram which illustrates the structure of another memory according to the present invention.

FIG. 20 is a diagram which illustrates the structure of another memory according to the present invention.

FIG. 21 is a block diagram which illustrates the structure of another storage system according to the present invention.

FIG. 22 is a block diagram which illustrates the structure of another storage system according to the present invention.

FIG. 23 is a block diagram which illustrates the structure of another storage system according to the present invention.

FIG. 24 is a flowchart of a process of duplicating file data according to the present invention.

FIG. 25 is a flowchart of another process of duplicating file data according to the present invention.

FIG. 26 is a flowchart of another process of duplicating block data according to the present invention.

FIG. 27 is a flowchart of a process of switching an access path according to the present invention.

FIG. 28 is a front plan view which illustrates the appearance of a storage system according to the present invention.

FIG. 29 is a perspective view which illustrates the appearance of another storage system according to the present invention.

### DESCRIPTION OF THE PREFERRED EMBODIMENT

### Structure of Storage System

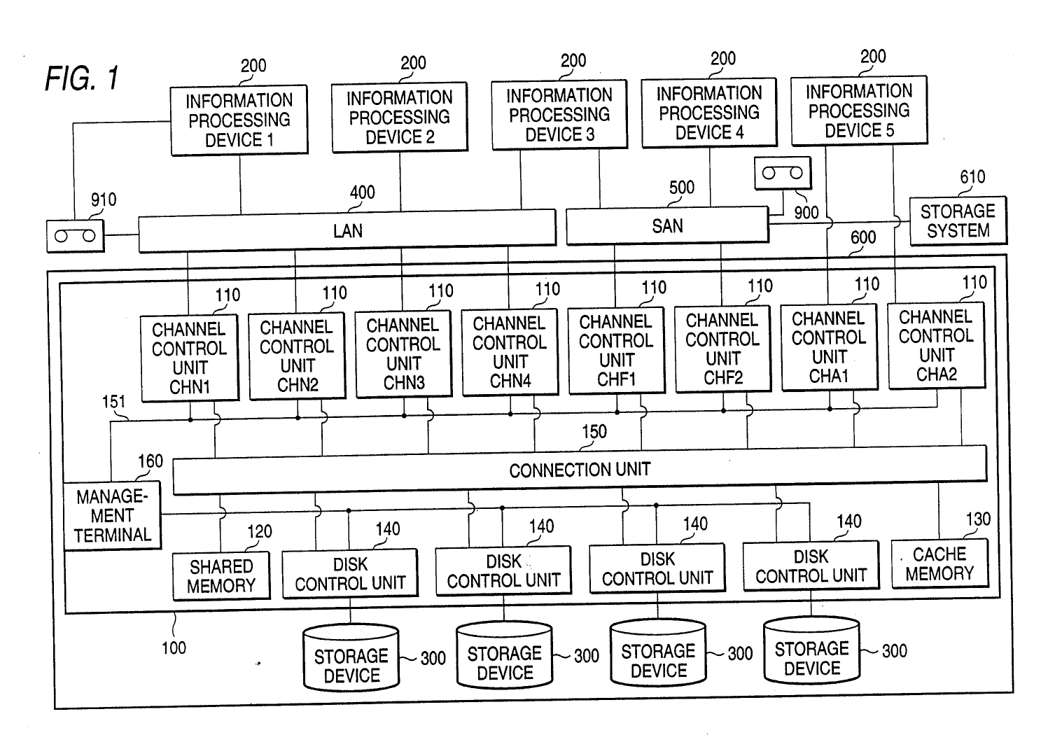

FIG. 1 illustrates the structure of a storage system 600 according to the present invention. The storage system 600 comprises a plurality of storage devices 300 and a storage device control apparatus 100 for controlling the input to and the output of data from the plurality of the storage devices 300 in response to an input/output request from an information-processing device 200. The information-processing device 200 is a computer apparatus having a CPU, a memory or the like, and it is, for example, a workstation, a main frame computer, or a personal computer. The information-processing device 200 can be comprised by connecting a plurality of the computers with a network. The information-processing device 200 contains an application program operated on an operating system. As examples of an application program, there are an automatic deposit and withdrawal system of the type used by a bank, a seat reservation system for an airplane, and the like.

The information-processing devices 1-3 (200) are connected with the storage system 600 through a Local Area Network (LAN) 400. The LAN 400 is a communication network, such as the Ethernet (registrated trademark) or FDDI, and the communication between the information-processing devices 1-3 (200) and the storage system 600 is performed by TCP/IP protocol. The data access request (the data input/output request in a file unit; hereinafter referred to as the file access request) according to the designation of the file name with respect to the storage system 600 is transmitted from the information-processing devices 1-3 (200) to the below-mentioned channel control unit CHN1-CHN4 (110).

The LAN 400 is connected to a backup device 910. The backup device 910 is, for example, a disk based device, such as a MO, CD-R or DVD-RAM, or a tape-based device, such as a DAT tape, a cassette tape, an open tape or a cartridge tape. The backup device 910 stores backup data corresponding to the data stored in the storage device 300 by communicating with the storage device control apparatus 100 through the LAN 400. In addition, the backup device 910 is connected with the information-processing device 1 (200), and it acquires the backup data corresponding to the data stored in the storage device 300 through the information-processing device 1 (200).

The storage device control apparatus 100 includes the channel control units CHN1-4 (110). The storage device control apparatus 100 controls the write access or read-access among the information-processing devices 1-3 (200), the backup device 910, and the storage devices 300 through the channel control units CHN1-4 (110) and the LAN 400. The channel control units CHN1-4 (110) receive a file access request from the information-processing devices 1-3 (200), respectively. In other words, the channel control units CHN1-4 (110) are allocated with network addresses (for example, IP addresses) on the LAN 400, respectively, and they are individually operated as a NAS. The NAS can individually provide the NAS service to the information-processing devices 1-3 (200) as if the NAS individually exists. By including the channel control units CHN1-4 (110) for individually providing the NAS service to one storage system 600, the NAS servers which were individually operated on separate computers in prior known systems are integrated in one storage system 600. Also, the storage system can be wholly managed and various settings and controls, or an efficiency of maintenance, such as obstacle management or version management, can be accomplished.

The information-processing devices 3-4 (200) are connected to the storage device control apparatus 100 through a SAN 500. The SAN 500 is a network for transmitting and receiving data to/from the information-processing devices 3-4 (200) using a block, which is a data management unit in the storage region provided by the storage device 300, as a unit. The communication performed between the information-processing devices 3-4 (200) and the storage device control apparatus 100 by the SAN 500 is performed according to a fiber channel protocol. The data access request (hereinafter referred to as a block access request) in a block unit is transmitted from the information-processing devices 3 and 4 (200) to the storage system 600 according to the fiber channel protocol.

The SAN 500 is connected with the backup device 900 corresponding to the SAN. The backup device 900 corresponding to the SAN communicates with the storage device control apparatus 100 through the SAN 500 and stores the backup data corresponding to the data stored in the storage device 300.

The storage device control apparatus 100 further includes channel control units CHF1-2 (110), in addition to the channel control units CHN1-4 (110). The storage device control apparatus 100 communicates with the information-processing devices 3 and 4 (200) and the backup device 900 corresponding to the SAN through the channel control units CHF1-2 (110) and the SAN 500.

Also, an information-processing device 5 (200) is connected directly with the storage device control unit 100 without using a network, such as the LAN 400 or the SAN 500. An example of the information-processing device 5 (200) is a mainframe computer. The communication between the information-processing device 5 (200) and the storage device control apparatus 100 is performed by a communication protocol, such as, for example, FICON (Fiber Connection; registrated trademark), ESCON (Enterprise System Connection; registrated trademark), ACONARC (Advanced Connection Architecture; registrated trademark), or FIBARC (Fiber Connection Architecture; registrated trademark). A block access request is transmitted from the information-processing device 5 (200) to the storage system 600 according to any one of the above-mentioned communication protocol.

The storage device control apparatus 100 communicates with the information-processing device 5 (200) through channel control units CHA1-2 (110).

The SAN 500 is connected with another storage system 610 provided at a location (a secondary site) remote from the location (a primary site) where the storage system 600 is positioned. The storage system 610 is used as a data replicating device having a replication or remote copy function. Also, the storage system 610 may be connected to the storage system 600 by a communication line, such as an ATM, in addition to the SAN 500. In this case, as the channel control unit 110 which is connected to the SAN 500, the channel control unit comprising an interface (channel extender) for using the communication line is used.

By integrating the channel control units CHN1-4 (110), the channel control units CHF1-2 (110) and the channel control units CHA1-2 (110) in the storage system 600, the storage system that is capable of being connected to dissimilar networks can be realized. That is, the storage system 600 is a SAN-NAS combined storage system, which is connected to the LAN 400 by using the channel control units CHN1-4 (110) and is connected to the SAN 500 by using the channel control units CHF1-2 (110).

A connection unit 150 connects each channel control unit 110, a shared memory 120, a cache memory 130 and each disk control unit 140 to each other. The transmission/reception of the command or the data among the channel control units 110, the shared memory 120, the cache memory 130 and the disk control units 140 is performed through the connection unit 150. The connection unit 150 is composed of a high-speed bus, such as a very high-speed crossbar switch, for transmitting the data by high-speed switching. Thereby, the communication performance among the channel control units 110 is remarkably improved and a high-speed file sharing function or high-speed failover can be accomplished.

The shared memory 120 and the cache memory 130 constitute the memory device shared by the channel control units 110 and the disk control units 140. The shared memory 120 is mainly used to store control information, a command, or the like, and the cache memory 130 is mainly used to store data. For example, in the case where a data input/output command which any channel control unit 110 receives from the information-processing device 200 is a write command, the corresponding channel control unit 110 writes the write command to the shared memory 120 and writes the write data received from the information-processing device 200 to the cache memory 130. On the other hand, the disk control unit 140 monitors the shared memory 120, and, if it is determined that the write command is written to the shared memory 120, the disk control unit 140 reads the write data from the cache memory 130 according to the write command and writes this data to the storage device 300.

On the other hand, in the case where a data input/output command which any channel control unit 110 receives from the information-processing device 200 is a read command, the corresponding channel control unit 110 writes the read command to the shared memory 120 and simultaneously determines whether or not the data to be read exists in the cache memory 130. Here, in the case where the data to be read exists in the cache memory 130, the channel control unit 110 reads the data from the cache memory 130 and transmits it to the information-processing device 200. In the case where the data to be read does not exist in the cache memory 130, the disk control unit 140, which detects that the read command is written to the shared memory 120, reads the data to be read from the storage device 300 and writes it to the cache memory 130, and writes that effect to the shared memory 120. If the channel control unit 110 detects that the data to be read is written to the cache memory 130 while monitoring the shared memory 120, the channel control unit 110 reads the data from the cache memory 130 and transmits it to the information-processing device 200.

The disk control unit 140 converts the data access request to the storage device 300, according to a logic address assignment transmitted from the channel control unit 110, into a data access request according to the physical address assignment and performs writing or reading of the data to/from the storage device 300 in response to the I/O request output from the channel control unit 110. In the case where the storage device 300 is composed of a RAID, the disk control unit 140 performs the data access according to the RAID. In addition, the disk control unit 140 performs the replication control or the remote copy control, in order to manage the replication of the data stored in the storage device 300, to control the backup, and to prevent the data from being lost due to fire (disaster recovery).

The storage device 300 comprises a single or a plurality of disk drives (physical volume) and provides a storage region that can be accessed from the information-processing device 200. In the storage region provided by the storage device 300, the physical volume combining the storage space of a single physical volume or a plurality of physical volumes is set. As the logic volume set to the storage device 300, there is a user logic volume that can be accessed from the information-processing device 200 or a system logic volume used for control of the channel control unit 110. The system logic volume stores an operating system executed in the channel control unit 110. Also, the logic volume provided by the storage device 300 is allocated with a logic volume which each of the channel control units 110 can access. Of course, a plurality of the channel control units 110 can share the same logic volume.

In addition, as the storage device 300, for example, a hard disk device or a flexible disk device can be used. As the storage structure of the storage device 300, a RAID type disk array can be constructed by a plurality of the storage devices 300. Further, the storage device 300 and the storage device control apparatus 100 can be directly connected to each other, or they can be connected to each other through the network. Also, the storage device 300 may be formed so as to be integral with the storage device control apparatus 100.

A management terminal 160 is a computer device for repairing and managing the storage system 600, and it is connected to each of the channel control units 110 and each of the disk control unit 140 through an internal LAN 151. By manipulating the management terminal 160, an operator can set up the disk drive of the storage device 300 or the logic volume, and can install the micro program executed in the channel control unit 110 or the disk control unit 140.

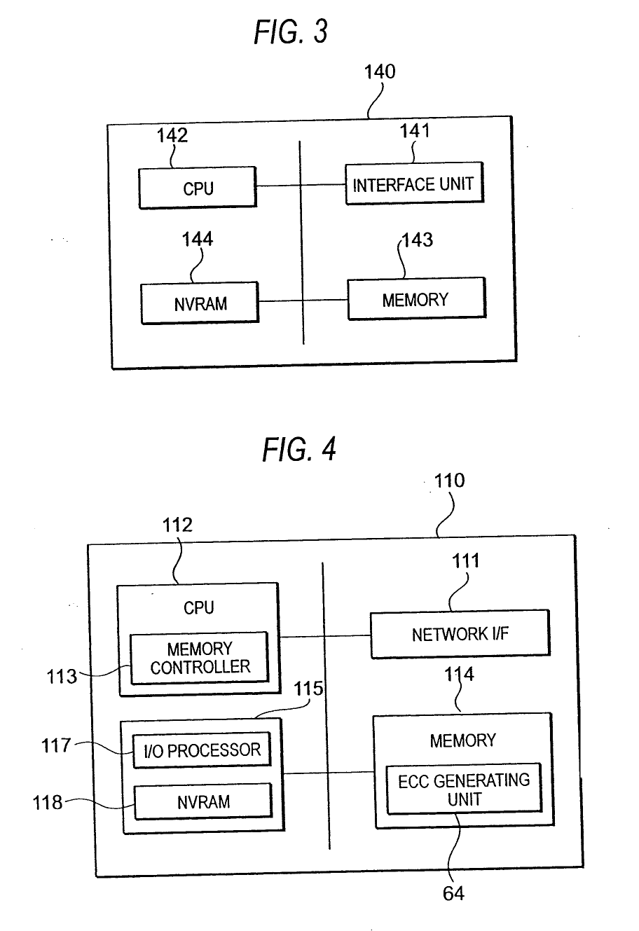

FIG. 3 illustrates the structure of the disk control unit 140. The disk control unit 140 comprises an interface unit 141, a CPU 142, a memory 143 and a NVRAM 144, all which are formed on a single substrate or a plurality of circuit substrates as an integral unit. The interface unit 141 comprises a communication interface for communicating with the channel control unit 110 or the like through the connecting unit 150 or a communication interface for communicating with the storage device 300. The CPU 142 communicates with the channel control unit 110, the storage device 300 and the management terminal 160 to perform access control for access to the above-mentioned storage device 300 or the replication management of the data. The memory 143 and the NVRAM 144 store a program, data or the like for allowing the CPU 142 to execute the above-mentioned various control processes.

### NAS-NAS Connection

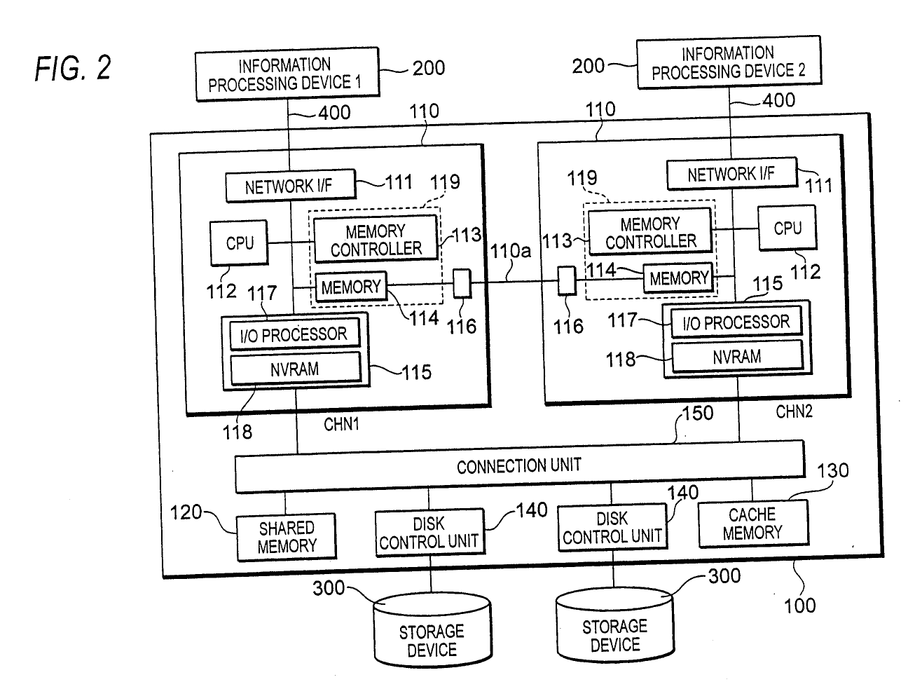

FIG. 2 illustrates the detailed structure of the channel control units CHN1-2 (110). In the present embodiment, a cluster composed of the channel control units CHN1 and CHN2 (110) is constructed, and a cluster composed of the channel control units CHN3 and CHN4 (110) is constructed. In FIG. 2, although the detailed structure of connecting the channel control units CHN3 and CHN4 (110) is not shown, the structure thereof is the same as that of the channel control units CHN1 and CHN2 (110). If the channel control units CHN1 and CHN2 (110) receive a file access request from the information-processing devices 1-3 (200), the channel control units CHN1 and CHN2 (110) acquire the storage address of the file or the data length and output the I/O request corresponding to the file access request to the storage device 300, thereby performing an access to the storage device 300. The I/O request contains a head address of the data, the data length, and the kind of access, such as a write access or a read access, and it further contains the write data in the case of the write access. Thereby, the file can be written from the information-processing devices 1-3 (200) to the storage device 300 by using a file transfer protocol, such as a NFS (Network File System) or a CIFS (Common Interface File System).

Each of the channel control units CHN1 and CHN2 (110) comprises a network interface 111, a CPU (NAS processor) 112, a memory controller 113, a memory (a memory module) 114, an input/output control unit 115, and a converting circuit (a converting LSI) 116, all which are formed on a single substrate or a plurality of circuit substrates as an integral unit. The network interface 111 is a communication interface for communicating with the information-processing device 200 according to the TCP/IP protocol, and it is composed of, for example, a LAN controller. The CPU 112 is a processor for allowing the channel control unit 110 to function as a NAS server. The memory 114 stores various programs and data, for example, an operating system, a volume manager, a file system program, a RAID manager, a SVP manager, a file system protocol (NFS or Samba etc.), a backup management program, an obstacle management program, a NAS manager, and a security management program. The memory controller 113 controls access to the memory 114 according to an instruction received from the CPU 112. The memory system 119 is composed of the memory 114 and the memory controller 113. The input/output control unit 115 includes an I/O processor 117 and a NVRAM (Non Volatile RAM) 118, and it transmits or receives the data or a command to or from the disk control unit 140, the cache memory 130, the shared memory 120 and the management terminal 160. The I/O request corresponding to the file access request is output by the I/O processor 117.

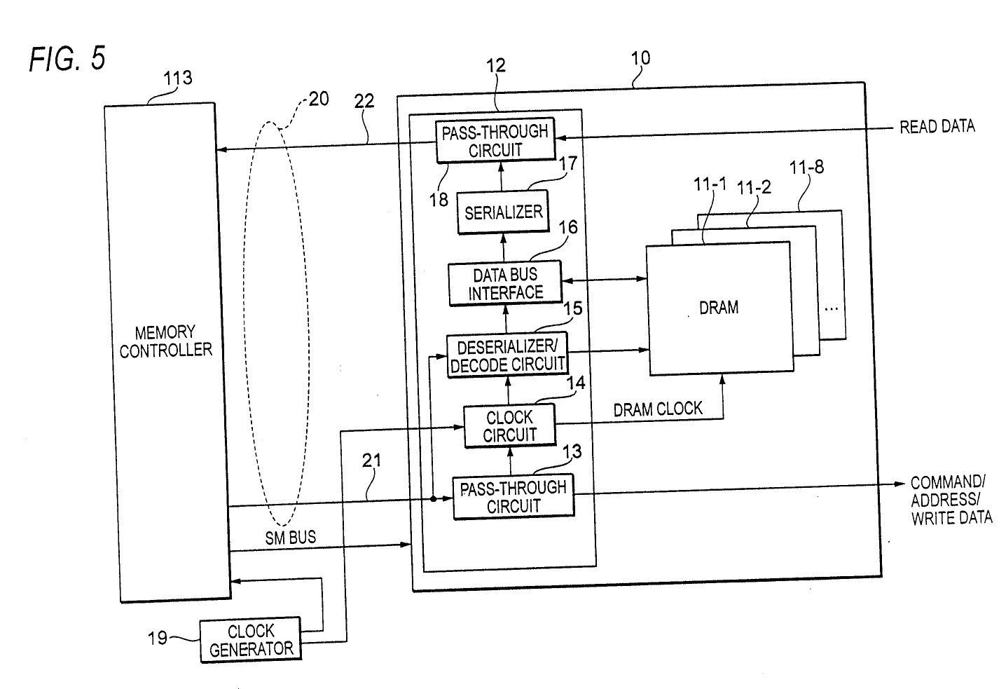

The channel control units CHN1 and CHN2 (110) comprising the cluster are constructed so as to mutually communicate the data by a signal line 110a, and thus they can share the data. In the case where the data is communicated between the channel control units CHN1 and CHN2 (110), since the distance between the units is long, a skew of the signal can be generated in the clock distribution structure. Accordingly, in the present embodiment, in consideration of the above-mentioned problem, a clock extracting structure is employed in the communication between the channel control units CHN1 and CHN2 (110). More specifically, since the memory 114 has a clock distribution structure operated by receiving the distributed clock signal from a clock generator 19 (See FIG. 5), the structure for converting the clock distribution type into the clock extraction type in the interface between the channel control units CHN1 and CHN2 (110) is employed. The data signal transmitted from the memory controller 113 to the memory 114 is 8B/10B-encoded and a clock is embedded in the data signal. The converting circuit 116 converts (decodes) the data signal from 10B to 8B, thereby extracting the embedded clock. The data identifying timing at the converting circuit 116 uses the clock signal supplied from the clock generator 19 as a reference. The converting circuits 116 included in each of the channel control units CHN1 and CHN2 (110) are connected through the signal line 110a. The channel control units CHN1 and CHN2 (110) can communicate data through the signal line 110a. For example, the memory controller 113 of the channel control unit CHN1 (110) can access the memory 114 of the channel control unit CHN2. In addition, the channel control units CHN1 and CHN2 (110) perform a hard bit communication through the signal line 110a, and thus failure of the concerned party can be detected.

### Appearance of the Storage System

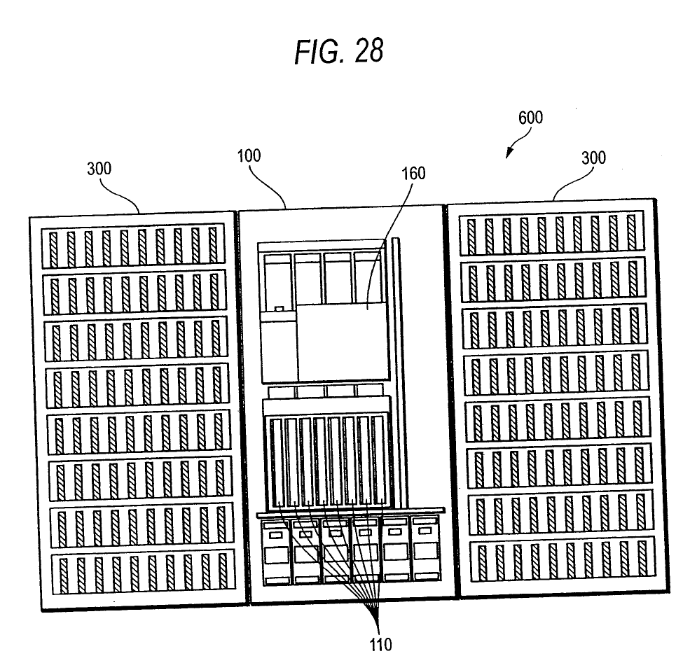

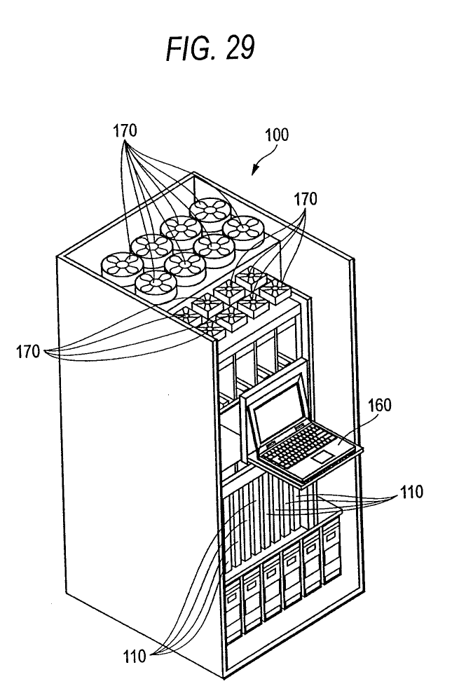

FIGS. 28 and 29 illustrate the outer appearance of the storage system 600. As shown in FIG. 28, the storage system 600 has a structure in which the storage device control device 100 and the storage device 300 are accommodated in each of respective chassis. At both sides of the chassis which holds the storage device control device 100, a chassis of the storage devices 300 is positioned. The storage device control apparatus 100 comprises a management terminal 160 at the front center thereof. The management terminal 160 is covered with a cover, and it can be used by opening the cover of the management terminal, as shown in FIG. 29. Here, the management terminal 160 shown in FIG. 29 has the form of a so-called notebook personal computer, but it is not limited to this. The storage device control apparatus 100 is formed with a fan arrangement 170 for emitting heat generated from the board of the channel control unit 110. The fan arrangement 170 is provided on the top surface of a slot for the channel control portion 110, as well as on the top surface of the storage device control apparatus 100.

At the lower portion of the management terminal 160, a slot is formed for mounting the board of the channel control unit 110. The board of the channel control unit 110 is a unit on which the circuit substrate of the channel control unit 110 is formed, and it is the unit mounted in the slot. In the storage system 600 related to the present embodiment, the number of slots is 8, and the boards of the channel control units 110 are mounted in the 8 slots as seen in FIGS. 28 and 29. Each slot is formed with a guide rail for mounting the board of the channel control unit 110. By inserting the board of the channel control unit in the slot along the guide rail, the board of the channel control unit 110 can be mounted on the storage device control apparatus 100. Also, the board of the channel control unit 110 mounted in each slot can be extracted and detached in a front direction along the guide rail. At the inner front portion of each slot, a connector is provided for electrically connecting the board of each channel control unit 110 with the storage device control apparatus 100. As the channel control unit 110, there are the channel control unit CHN1 and CHN4 (110), the channel control unit CHF1 and CHF2 (110), and the channel control unit CHA1 and CHA2 (110). However, since any board of the channel control unit 110 has compatibility with respect to the size or the location of the connector, or the pin arrangement of the connector, any board of the channel control unit 110 can be mounted in the 8 slots.

In the channel control unit 110 in each slot, a plurality of the channel control units 110 of the same kind compose a cluster. For example, a pair of the channel control units CHN1 and CHN2 (110) and a pair of the channel control units CHN3 and CHN4 (110) compose clusters. By composing a cluster, in the case where an obstacle is generated at any channel control unit 110 in the cluster, the process which was performed by the channel control unit 110 in which the obstacle is generated at that time can be continuously performed in the other channel control unit 110 in the cluster.

In the storage device control apparatus 100, power is supplied from two power supply systems in order to improve the reliability, and 8 slots in which a board of the channel control unit 110 is mounted are divided by 4 for the power supply system. Accordingly, in the case of composing a cluster, boards of the channel control units 110 each belonging to each of two power supply systems must be included. Thereby, even though an obstacle is generated in one power supply system thereby to stop supplying power, the power is continuously supplied to the board of the channel control unit 110 belonging to the other power supply system composing the same cluster, and, thus, the process at the channel control unit 110 can be continued.

In addition, the channel control unit 110 is provided as a board which can be mounted in each slot, as mentioned above, and one board can be composed of a plurality of integrally formed circuit substrates. Also, while the other devices composing the storage device control apparatus 100, such as the disk control unit 140 or the shared memory 120, are not shown in FIGS. 28 and 29, they are mounted on the back surface of the storage device control apparatus 100.

However, as the storage device control apparatus 100 and the storage device 300 accommodated in each chassis, conventional devices corresponding to the SAN can be used. Particularly, the connector of the board of the channel control units CHN1-CHN4 (110) is shaped such that it can be mounted in the slot formed in a conventional chassis, and, thus, the device can be more simply used. In other words, the storage system 600 of the present embodiment can be easily constructed by using an existing product.

### Structure of FB-DIMM

FIG. 5 illustrates the function block of the FB-DIMM 10. The FB-DIMM 10 can be used as a component of the hardware resource for storing various data, which is formed in the storage device control apparatus 100, and it is applied as a component of the above-mentioned memory 114 mentioned in the embodiments described below. In the explanation of the detailed structure of the circuit in the memory 114, the structure of the FB-DIMM 10 will be explained first. A plurality of FB-DIMMs 10 are connected to form the memory 114, and each FB-DIMM 10 is connected to the memory controller 113 through a serial interface. FIG. 5 shows the detailed structure of one FB-DIMM 10, and the FB-DIMM 10 and the memory controller 113 are serially connected to each other by the serial interface signal line 20. The serial interface signal line 20 comprises a serial interface signal line 21 for serially transmitting a command, the address and the write data from the memory controller 113 to the FB-DIMM 10 and a serial interface signal line 22 for serially transmitting the read data from the FB-DIMM 10 to the memory controller 113. Also, regardless of the number of the serial interface signal lines 21, 22, if the command, the address and the data can be serially transmitted between the memory controller 113 and the FB-DIMM 10 (memory resource), this corresponds to the “serial interface” mentioned in the present embodiment. Here, the “serial interface” in the present embodiment includes the component used for transmitting various signals (command, address or data, etc.) between the memory controller and the memory module (FB-DIMM) and between the memory modules (FB-DIMMs), that is, a serial interface signal line and a memory interface unit (also referred to as a port).

The FB-DIMM 10 organizes a plurality of DRAMs, which are the memory elements to a module. The FB-DIMM 10 includes 8 DRAMs 11-1, 11-2, . . . , 11-8 mounted on the DIMM module substrate and a buffer unit (advanced memory buffer) 12 for buffering the packet type of the command, the address and the data that is serially transmitted from the memory controller 113 through the serial interface signal line 20, for interpreting the command, and for controlling the memory access to the DRAMs 11-1, 11-2, . . . 11-8. An FB-DIMM 10 can be connected to the other FB-DIMMs 10 through the buffer unit 12 in a daisy chain manner. In the case where a plurality of the FB-DIMMs 10 are connected to each other through the buffer unit 12 in the daisy chain manner, the buffer unit 12 references the address transmitted from the memory controller 113, and, in the case that it is not the command which is transmitted to its own FB-DIMM, transmits the command to the next FB-DIMM 10. Also, there are various kinds of DRAMs mounted on the FB-DIMM 10 and the structure mentioned herein is only an example thereof.

The buffer unit 12 comprises a pass-through circuit 13, a clock circuit 14, a deserializer/decode circuit 15, a data bus interface 16, a serializer 17, and a pass-through circuit 18. Whether or not the command, which is supplied from the memory controller 113 to the FB-DIMM 10 through the serial interface signal line 21, is a command transmitted to its own FM-DIMM 10 is determined by the pass-through circuit 13. In the case that it is not a command transmitted to its own FB-DIMM, the command passes through and is transmitted to the next FB-DIMM 10. In the case that it is a command transmitted to its own FB-DIMM, the command is interpreted in the deserializer/decode circuit 15. In the case that the command is the write command, the write address and a write data are supplied to the deserializer/decode circuit 15, subsequent to the corresponding command. The deserializer/decode circuit 15 outputs a control signal for effecting write access to the DRAMs 11-1, 11-2, . . . , 11-8 and coverts the write data into parallel data to output it to the DRAMs 11-1, 11-2, . . . , 11-8 through the data bus interface 16. On the other hand, in the case that the command is a read command, the read address is supplied to the deserializer/decode circuit 15, subsequent to the corresponding command. The deserializer/decode circuit 15 outputs a control signal for effecting read-access to the DRAMs 11-1, 11-2, . . . , 11-8. The read data read from the DRAMs 11-1, 11-2, . . . , 11-8 is transmitted to the serializer 17 through the data bus interface 16 and is converted into serial data. The pass-through circuit 18 transmits the read data which has been read from the DRAMs 11-1, 11-2, . . . , 11-8 or the read data that is transmitted from a subsequent FB-DIMM 10 to the memory controller 113 through the serial interface signal line 22.

In addition, the clock circuit generates the DRAM clock required for accessing the memory 14 on the basis of the reference clock generated by the clock generator 19. Also, the memory controller 113 performs a peer-to-peer communication with the FB-DIMM 10 through a SM (System Management) bus 22 to perform system management or power management. By employing the FB-DIMM 10 having a serial interface as the storage device in the storage device control apparatus 100, memory access of the storage device control apparatus 100 can be performed at high speeds and the circuit components can be easily mounted.

### Duplication of the Interface

In the present embodiment, the serial interface signal line 20 is connected between the memory controller 113 and the FB-DIMM 10 and between the FB-DIMMs 10, and a “duplication of the serial interface” is performed. Here, the “duplication of the serial interface” includes the fail safe countermeasure that the memory access can be performed from the memory controller 113 to the FB-DIMM 10 even if an obstacle is generated in the serial interface signal line 20, and it provides, for example, (1) duplication of the write data, (2) duplication of the access path, (3) a duplication of the serial interface signal line, and the combination thereof. That is, as the “duplication of the serial interface”, there are the case in which a single serial interface between the memory controller 113 and the FB-DIMM 10 is duplicated (the above-mentioned case (3)), the case in which the access path due to the serial interface connection between the memory controller 113 and the FB-DIMM 10 is duplicated (the above-mentioned case (2)), or the case in which the same data is read/written from/to each of the different FB-DIMMs 10 to/from the memory controller 113 by two systematic serial interfaces (the above-mentioned case (1)). Hereafter, each pattern will be described.

### Duplication of the Write Data

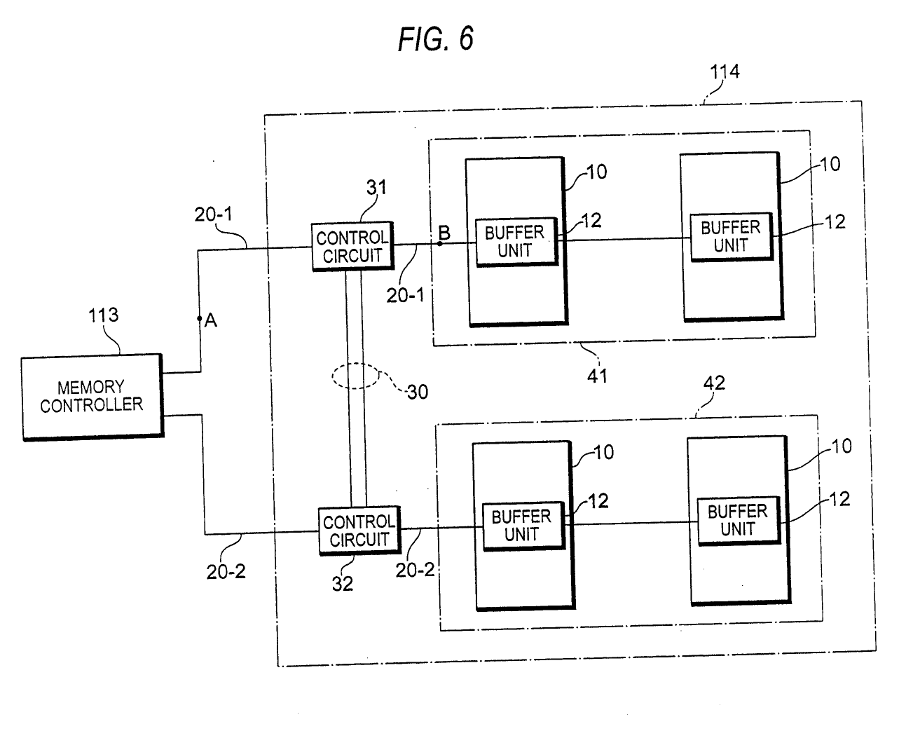

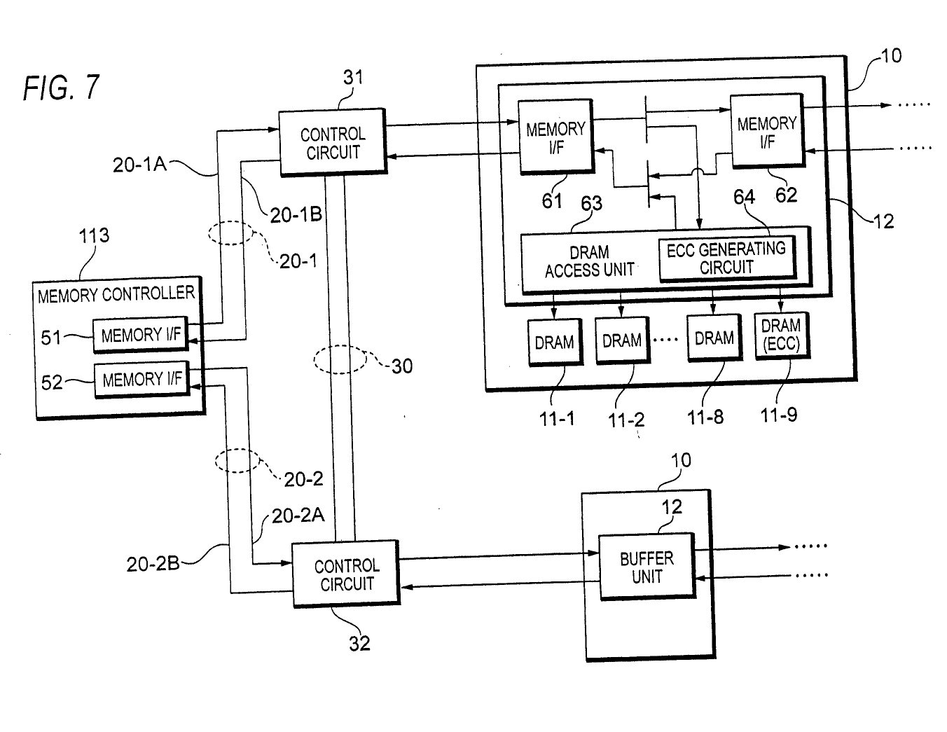

FIG. 6 illustrates the structure of the memory 114 for performing duplication of the write data. The memory 114 comprises a first systematic memory module group 41 composed by connecting a plurality of the FB-DIMMs 10 in the daisy-chain manner and a second systematic memory module group 42 composed by connecting a plurality of the FB-DIMMs 10 in the daisy-chain manner. Each of the memory module groups 41, 42 is connected with the memory controller 113 through the serial interface signal lines 20-1, 20-2. Each of the serial interface signal lines 20-1, 20-2 comprises serial interface signal lines 20-1A, 20-2A for serially transmitting the command, the address and the write data from the memory controller 113 to the FB-DIMM 10 and serial interface signal lines 20-1B, 20-2B for serially transmitting the read data from the FB-DIMM 10 to the memory controller 113, as shown in FIG. 7. Each of the serial interface signal lines 20-1, 20-2 is provided with control circuits 31, 32 for controlling the switching of the memory access path from the memory controller 113 to the FB-DIMM The control circuits 31, 32 are connected to each other through the signal line 30, and they can transmit/receive command or data to/from each other. The memory controller 113 operates together with the control circuits 31, 32 and performs a memory access to the memory module groups 41, 42. When a write access to any one of the memory module group 41 and the memory module group 42 is performed, a duplication of the write data is performed by writing the write data to the other memory module group. That is, in order to dually write the write data, two systematic serial interface signal lines 20-1, 20-2 are provided and two systematic access paths for reading/writing the same data from/to different FB-DIMMs 10 are prepared. By this structure, although an obstacle may be generated in any one of the systematic memory module groups 41, 42 and/or the serial interface signal lines 20-1, 20-2, memory access can be performed by the other systematic memory module group or the other serial interface signal line (failover). In this case, when the first system is an operating system (or a primary system) and the second system is a waiting system (or a dependent system), the memory controller 113 can control them so that the same data as the data written to the first systematic memory module group 41 is written to the second systematic module group 42. Thereby, the memory controller 113 can access the second systematic module group 42, if an obstacle is generated in the first systematic memory module group 41 and/or the serial interface signal line 20-1.

The process for dually writing the same write data to each of the memory module groups 41, 42 will be explained. For example, the memory controller 113 accesses the control circuit 31 and/or the control circuit 32 through the serial interface signal lines 20-1, 20-2 and controls the switching control resource of the control circuit 31 and/or the control circuit 32, for example, the switching LSI, and adequately selects the access path to the memory module groups 41, 42 so as to dually write the same write data to the memory module groups 41, 42. Alternately, the memory controller 113 sends the write command, the address, and the write data to any one side or both sides of the control circuits 31 and 32, and the control circuit 31 or 32 will dually write the same write data as the write data received from the memory controller 113 to the memory module groups 41, 42. In the latter case, for example, the memory controller 113 sends the write command, the address, and the write data to the control circuit 31, and the control circuit 31 writes the write data to the first systematic memory module group 41. Again, the control circuit 31 transmits the write command, the address, and the write data to the control circuit 32 through the signal line 30, and the control circuit 32 writes the write data to the second systematic memory module group 42.

As the process of reading the write data from the memory module groups 41, 42 by the memory controller 113, various procedures can be considered. For example, the data may be read from any one of the systematic memory module groups 41, 42. Alternately, the data may be read from both systematic memory module groups 41, 42, whereby if both data are identical, it is determined that the data does not have an error, and, if both data are not identical, the error is corrected.

As a fail-safe countermeasure when an obstacle is generated in any one of the serial interface signal lines 20-1, 20-2, the below-mentioned process will be considered. For example, when an obstacle is generated in the serial interface signal line 20-1 between the memory controller 113 and the control circuit 31 (the point A in FIG. 6), the memory controller 113 detects that it can not access the control circuit 31 by the below-mentioned method and sends a write command, the address and the write data to the control circuit 32. The control circuit 32 writes the write data to the second systematic memory module group 42 and transmits the write command, the address and the write data to the control circuit 31 again. The control circuit 31, which has received the write command, the address and the write data from the control circuit 32, writes the write data to the first systematic memory module group 41. In addition to the above-mentioned point A, in the case that an obstacle is generated in the serial interface signal line 20-1 between the control circuit 31 and the first systematic memory module group 41 (the point B in FIG. 6), the control circuit 31 which has received the write command, the address and the write data from the control circuit 32 can not write the write data to the first systematic memory module group 41. Here, the generation of an obstacle at the point A or the point B can be detected by whether or not there is a response for the memory access (for example, whether or not there is an acknowledge signal indicating the completion of the memory access or whether or not the read data for the read-access is transmitted). Alternately, in the case in which the response is not returned from each of the memory module groups 41, 42, the control circuits 31, 32 detect that an obstacle has been generated in any one location of the serial interface signal lines 20-1, 20-2 connecting each of the systematic memory module groups 41, 42 or in the FB-DIMM 10 belonging to each of the memory module groups 41, 42 and exchanges information indicating whether an obstacle has been generated as status information. By exchanging the information indicating whether or not an obstacle has been generated, the control circuit 32 need not transmit the write command, the address and the write data to the control circuit 31 in the case where it is detected that an obstacle has been generated, for example, at the point B.

On the other hand, in the case where obstacle has been generated at the point A, when the memory controller 113 performs a read-access, the read command and the address are sent to the control circuit 32 to read the data from the second systematic memory module group 42, or the read command and the address are transmitted from the control circuit 32 to the control circuit 31, such that the control circuit 31 read the data from the first systematic memory module group 41. In the case where an obstacle has been generated at the point B in addition to the point A, the memory controller 113 may access the second systematic memory module group 42 through the control circuit 32.

FIG. 7 illustrates the structure of the memory 114 having an ECC (Error Checking and Correction) function in addition to the duplication of the write data. The ECC applied to the data written to the FB-DIMM 10 can be generated by the memory controller 113. If the number of the FB-DIMMs 10 is increased, the load of the memory controller 113 is increased. Also, in the case in which data is serially transmitted from the memory controller 113 to the FB-DIMM 10 through the serial interface signal lines 20-1, 20-2, although the ECC is generated at the side of the memory controller 113 and the ECC is applied to the serially transmitted signal, the effect can not be accomplished. Accordingly, by mounting the ECC function at the side of the FB-DIMM 10, the load of the memory controller 113 is reduced and the error of the write data code due to the data storage failure of the DRAMs 11-1, 11-2, . . . , 11-8 can be corrected. Thereby, the reliability of the data according to the ECC can be improved, in addition to the duplication of the write data. Also, the data serially transmitted from the memory controller 113 to the FB-DIMM 10 is divided into block units and a CRC (Cyclic Redundancy Check) is applied thereto. The data receiving side can detect an error by checking whether or not the relationship between the received data and the CRC is correct.

The buffer unit 12 of the FB-DIMM 10 comprises memory interface units 61, 62 and a DRAM access unit 63. The DRAM access unit 63 comprises an ECC generating unit 64 for generating the ECC. The memory interface units 61, 62 are composed of the above-mentioned pass-through circuits 13, 18. The DRAM access unit 63 is composed of the above-mentioned clock circuit 14, the deserializer/decode circuit 15, the data bus interface 16, and the serializer 17. The memory controller 113 comprises the memory interface units 51, 52 which are connected to the serial interface signal lines 20-1, 20-2, respectively.

When a write access to the FB-DIMM 10 is performed, the ECC generating unit 64 calculates the ECC depending on the write data. As the ECC, for example, a hamming code, with which a 2-bit error can be detected and 1-bit error can be detected and corrected is suitable. The ECC calculated by the ECC generating unit 64 is written to the DRAM 11-9 for storing the ECC. By applying the ECC function in the FB-DIMM 10, the ECC generating unit 64 need not be mounted on the memory controller 113, and, thus, the circuit size of the memory controller 113 can be reduced. If the circuit size of the memory controller 113 is reduced, the memory controller 113 can be mounted in the CPU 112, as shown in FIG. 4.

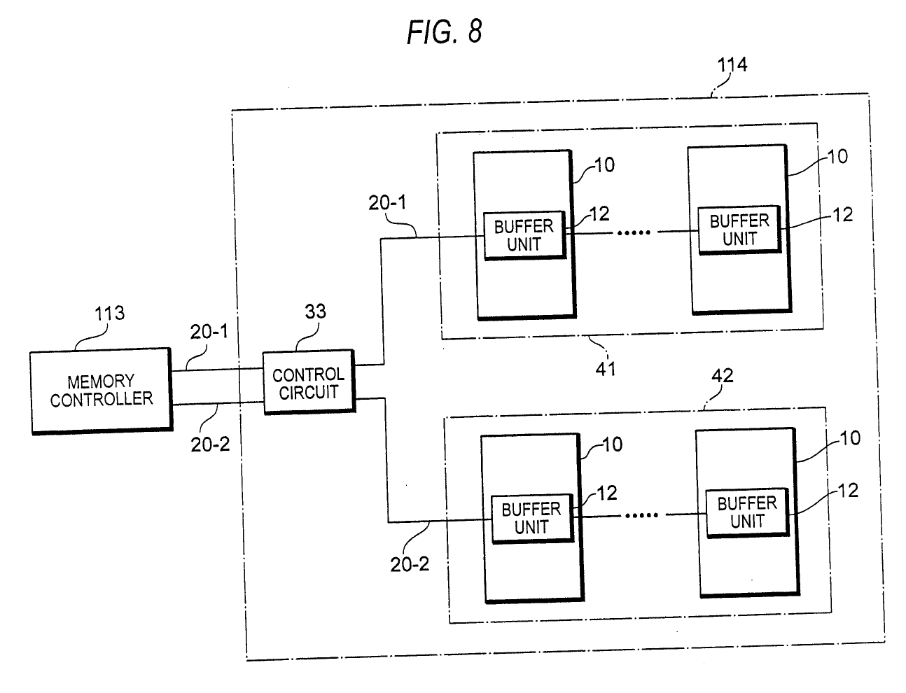

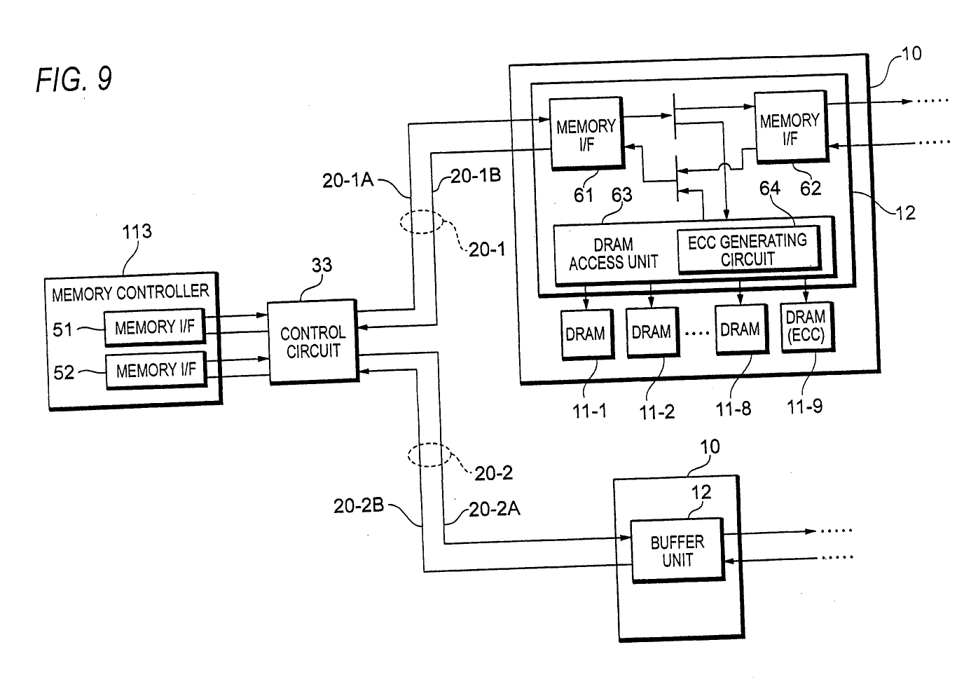

FIG. 8 illustrates the other structure of the memory 114 for performing the duplication of the write data. In this figure, the control circuit 33 also performs the function of the above-mentioned control circuits 31, 32 and the switching control of the memory access path for dually writing the write data to the memory module groups 41, 42 is performed by the control circuit 33. By applying the function of a plurality of the control circuits 31, 32 to the single control circuit 33, the circuit size of the memory 114 can be reduced. FIG. 9 illustrates the structure of the memory 114 applying the ECC function to the FB-DIMM 10, in addition to the structure of FIG. 8.

### Duplication of the Access Path

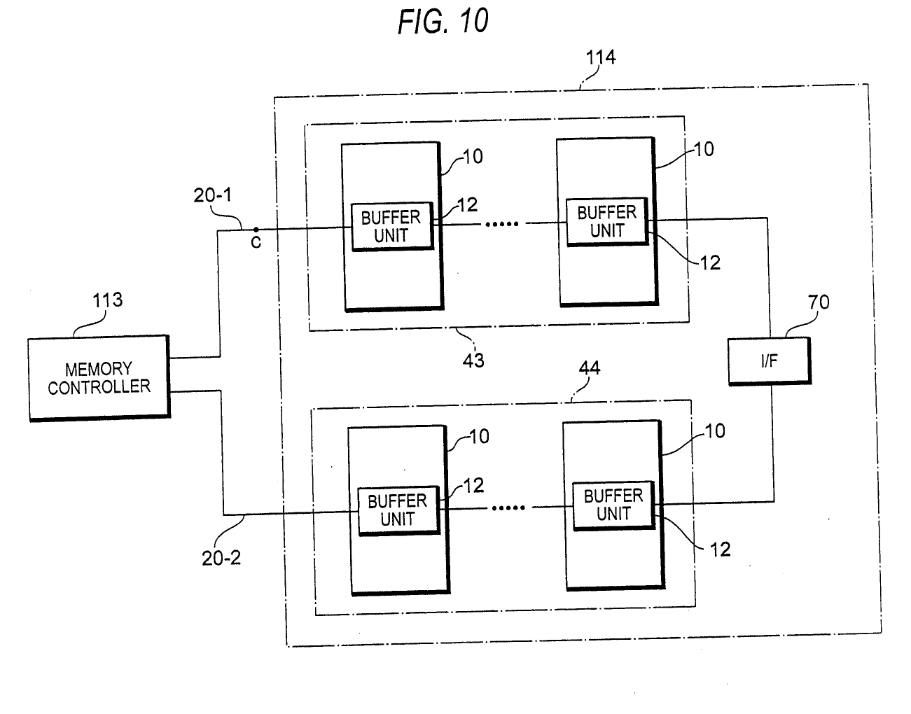

FIG. 10 illustrates the structure of the memory 114 for duplicating the access path from the memory controller 113 to the FB-DIMM 10. The memory 114 comprises a plurality of the FB-DIMMs 10 loop-connected with the memory controller 113 by the serial interface signal lines 20-1, 20-2. The ends of the serial interface signal lines 20-1, 20-2 are connected to each other by the interface circuit 70. The interface circuit 70 delivers the memory access from the serial interface signal line 20-1 to the serial interface signal line 20-2 and the memory access from the serial interface signal line 20-2 to the serial interface signal line 20-1. The plurality of FB-DIMMs 10 are loop-connected to each other in a daisy-chain manner and are divided into a first systematic memory module group 43, which is connected from the memory controller 113 to the interface circuit 70 through the serial interface signal line 20-1, and a second systematic memory module group 44, which is connected from the memory controller 113 to the interface circuit 70 through the serial interface signal line 20-2.

The memory controller 113 is constructed such that memory access can be performed in the bi-direction of the loop with respect to the loop-connected FB-DIMM 10. In this way, by duplicating the access path to the FB-DIMM 10, although an obstacle may be generated in any one access path (memory controller 113→serial interface signal line 20-1→FB-DIMM 10), a memory access can be performed through the other access path (memory controller 113→serial interface signal line 20-2→FB-DIMM 10). For example, in a case in which an obstacle is generated between the memory controller 113 and the FB-DIMM 10 (the point C in FIG. 10), the memory controller 113 can not access the FB-DIMM 10 through the serial interface signal line 20-1, but it can access the FB-DIMM 10 through the serial interface signal line 20-2 and can perform a memory access from the interface circuit 70 to the FB-DIMM 10 through the interface signal line 20-1. In this way, by switching the access path, the location of the serial interface signal lines 20-1, 20-2 at which the obstacle is generated can be specified.

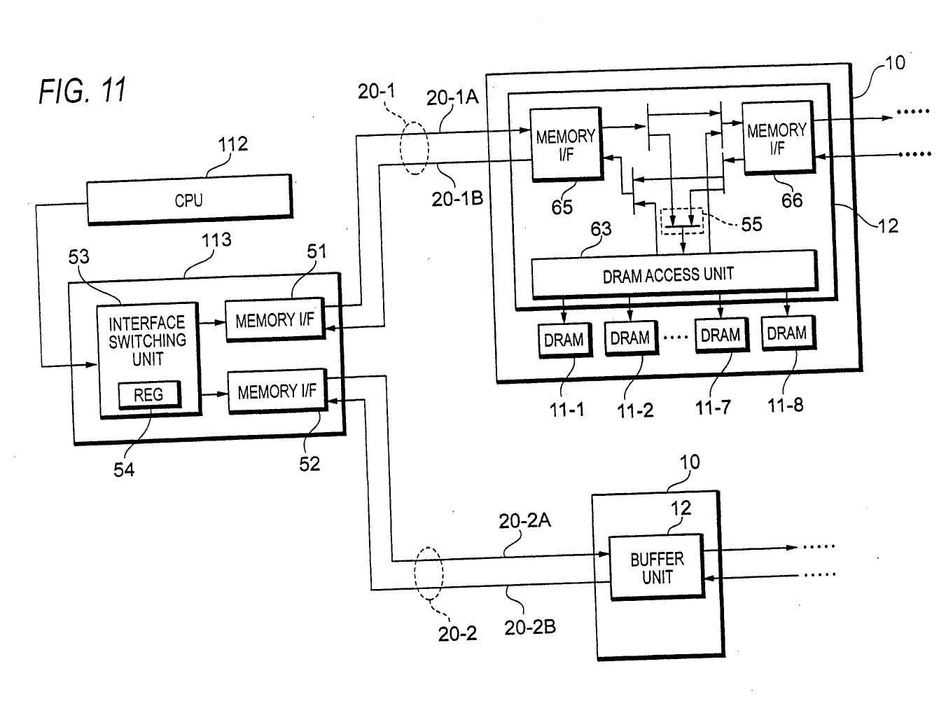

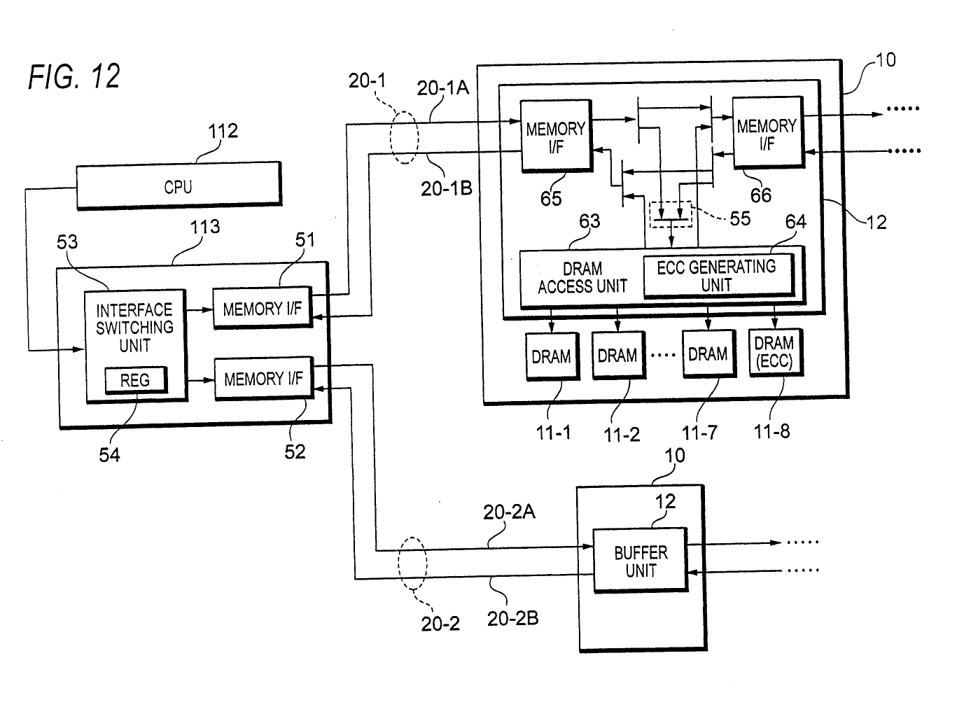

FIG. 11 illustrates the detailed structure of the memory 114 for duplicating the access path. The buffer unit 12 of the FB-DIMM 10 comprises memory interface units 65, 66 which can perform a memory access from the bi-direction of the loop. The buffer unit 12 comprises an exclusive control unit 55 for allowing any one memory access with respect to the memory accesses which are simultaneously performed from the bi-direction of the loop, that is, the memory accesses which are simultaneously performed from the memory interface units 65, 66. The memory controller 113 comprises an interface switching unit 53, in addition to the above-mentioned memory interface units 51, 52. The interface switching unit 53 selects any one of the memory interface units 51, 52 to be used for a memory access, according to the set content in an initial set register 54, when receiving a memory access request from the CPU 112. The initial set register 54 is set with the memory interface unit 51 or 52 to be generally used after performing the memory access, with respect to each FB-DIMM 10. For example, the memory interface unit 51 is generally used for the FB-DIMM 10 belonging to the first systematic memory module 43, and the memory interface unit 52 is generally used for the FB-DIMM 10 belonging to the second systematic memory module 44. The set content in the initial set register 54 is not limited to the above-mentioned example. The memory interface unit 51 or 52 to be generally used may be set according to the memory address, or the memory interface 51 or 52 to be used for the memory access may be dynamically switched according to the frequency of use of the memory interface units 51, 52. FIG. 12 illustrates the structure of the memory 114 in which the ECC function is applied to the FB-DIMM 10, in addition to the structure of FIG. 11. The description of the ECC function is the same as that of FIG. 7.

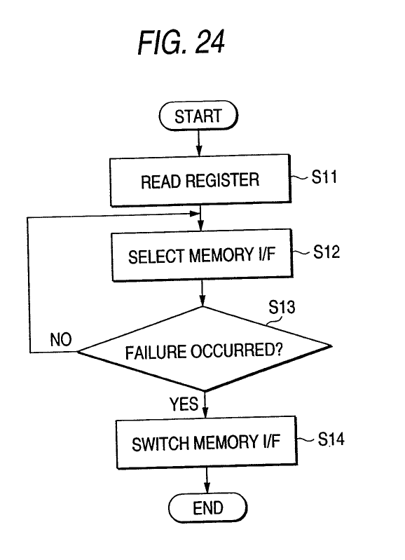

FIG. 24 is a flowchart illustrating the switching process applied to the access path to be used for a memory access. If the system is operated, the memory controller 113 reads the set content in the initial set register 54 (S11), and selects the memory interface unit 51 or 52 which is an access point according to the set content (S12). Subsequently, whether an obstacle has been generated in the serial interface signal line 20-1 or 20-2 is determined (S13), and, if the obstacle has not been generated (S13; NO), the connection state of the memory controller 113 to the memory interface unit 51 or 52, which is an access point, is maintained. As soon as the obstacle is not generated, the loop of S12-S13 is repeated. If an obstacle has been generated in the serial interface signal line connected to the memory interface unit which is an access point (S13; YES), the memory controller 113 selects the other memory interface unit as the memory interface unit which represents an access point (S14).

### Duplication of the Interface Signal Line

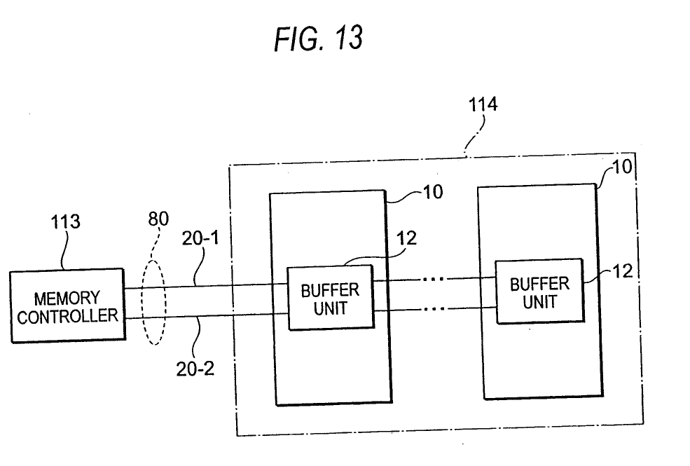

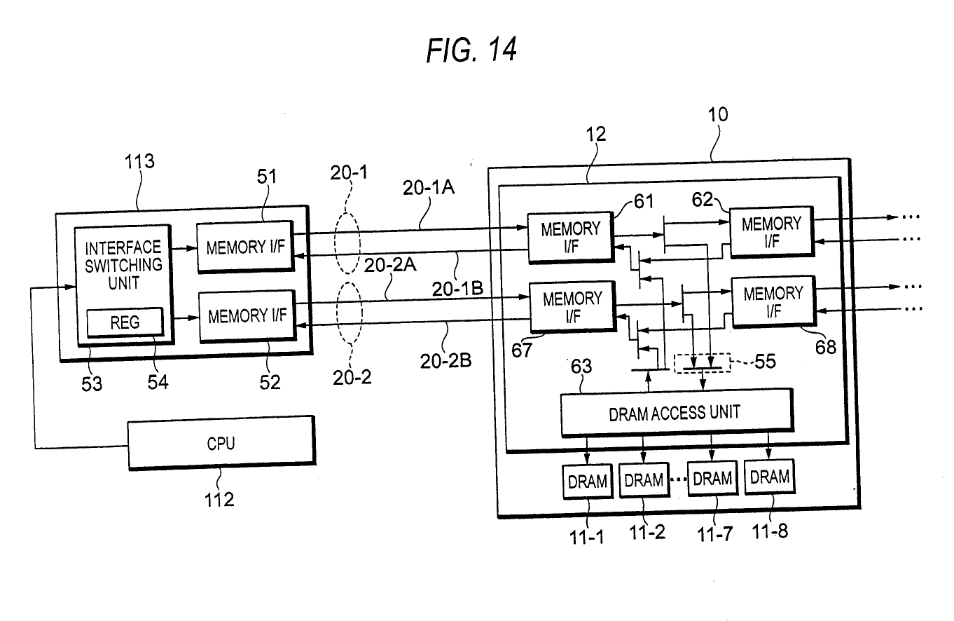

FIG. 13 illustrates the structure of the memory 114 in which the serial interface signal line 80 composing the single serial interface between the memory controller 113 and the memory 114 is duplicated. The memory 114 comprises a plurality of FB-DIMMs 10 connected to each other in a daisy chain manner. The buffer units 12 of the plurality of FB-DIMMs 10 are serially connected to each other through the serial interface signal line 80. The serial interface signal line 80 is duplicated by a pair of the serial interface signal lines 20-1, 20-2. Each of the serial interface signal lines 20-1, 20-2 comprises the serial interface signal lines 20-1A, 20-2A for serially transmitting a command, the address and the write data from the memory controller 113 to the FB-DIMM 10, and the serial interface signal lines 20-1B, 20-2B for serially transmitting the read data from the FB-DIMM 10 to the memory controller 113, as shown in FIG. 14. By duplicating the serial interface signal line 80 composing the single serial interface, although an obstacle may be generated in any one serial interface signal line 20-1 (or 20-2), the memory access to the FB-DIMM 10 can be performed through the other serial interface signal line 20-2 (or 20-1). Also, the serial interface signal line 80 may be multiplexed to 3 or more.

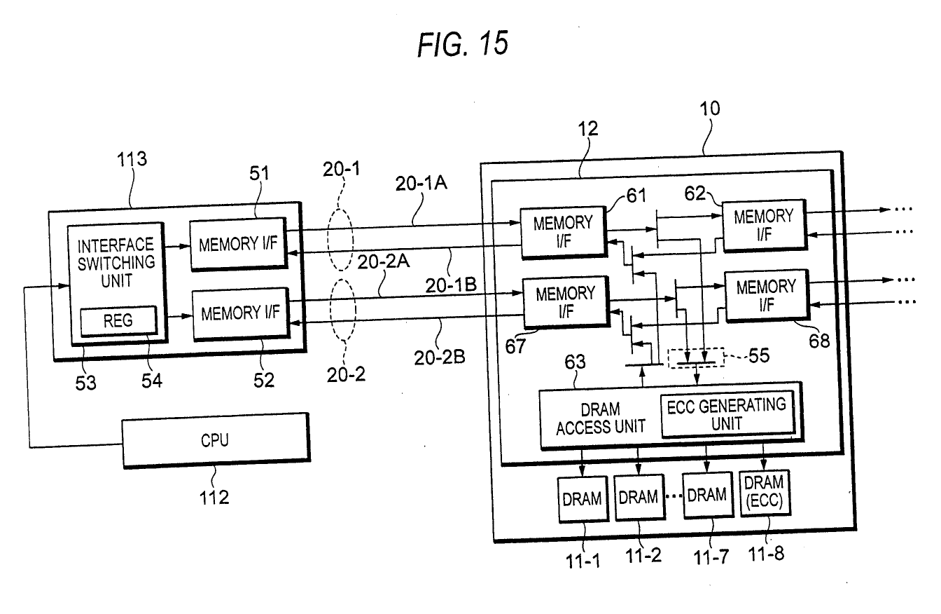

FIG. 14 illustrates the detailed structure of the memory 114 in which the interface signal line is duplicated. The buffer unit 12 of the FB-DIMM 10 comprises memory interface units 61, 62, 67, 68 which can perform a memory access from the memory controller 113 through the serial interface signal lines 20-1, 20-2 from the same direction (one direction). The buffer unit 12 comprises the exclusive control unit 55 for allowing any one memory access, with respect to the memory accesses which are actually simultaneously performed from the same direction through the serial interface signal lines 20-1, 20-2, that is, the memory accesses which are actually simultaneously performed from the bi-direction of the memory interface units 61, 67. The interface switching unit 53 of the memory controller 113 selects any one of the memory interface units 51 and 52 to be used for the memory access according to the set content in the initial set register 54, when receiving the memory access request from the CPU 112. The initial set register 54 is set with the information of the memory interface unit 51 or 52 to be generally used after performing the memory access. For example, the content for which the memory interface unit 51 connected to the serial interface signal line 20-1 is generally used is set. The set content in the initial set register 54 is not limited to the above-mentioned example, and the information of the memory interface unit 51 which is generally used may be set according to the memory address, or the memory interface unit 51 or 52 which is used for the memory access may be dynamically switched according to the frequency of use of the memory interface unit 51 or 52. The switching process of the serial interface signal lines 20-1, 20-2 to be used for the memory access is the same as the process of FIG. 24. FIG. 15 illustrates the structure of the memory 114 in which the ECC function is applied to the FB-DIMM 10, in addition to the structure of FIG. 14.

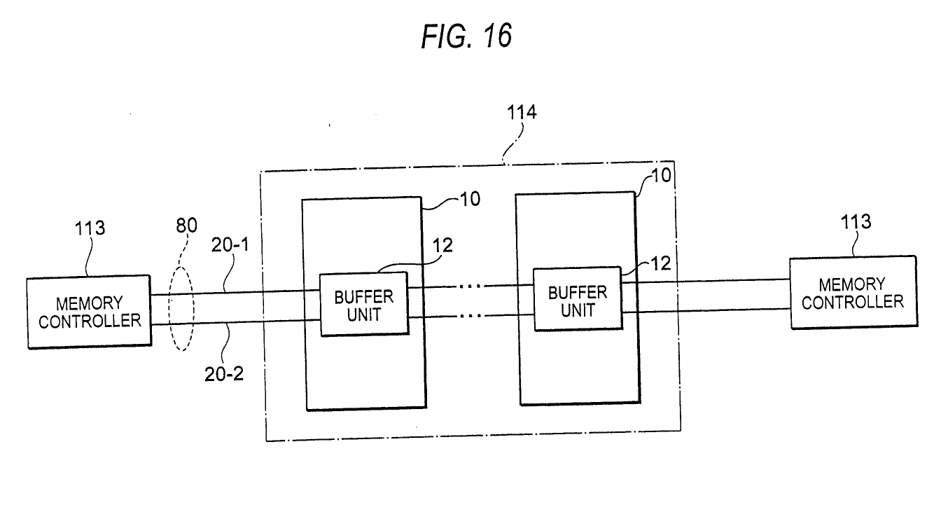

FIG. 16 illustrates the other structure of the memory 114 in which the interface signal line is duplicated. The memory 114 comprises a plurality of FB-DIMMs 10 which are connected to each other in a daisy-chain manner, and both ends thereof are provided with a memory controller 113. In this structure, the memory 114 is constructed such that a memory access can be performed from the bi-direction of the serial interface signal line 80 and the memory controller 113, and the serial interface signal line 80 can be duplicated as well. By duplicating the serial interface signal line 80 and the memory controller 113, respectively, the reliability of the memory system can be increased. Also, the memory access can be performed from the bi-direction of the serial interface signal line 80, thereby the location at which the obstacle is generated can be specified.

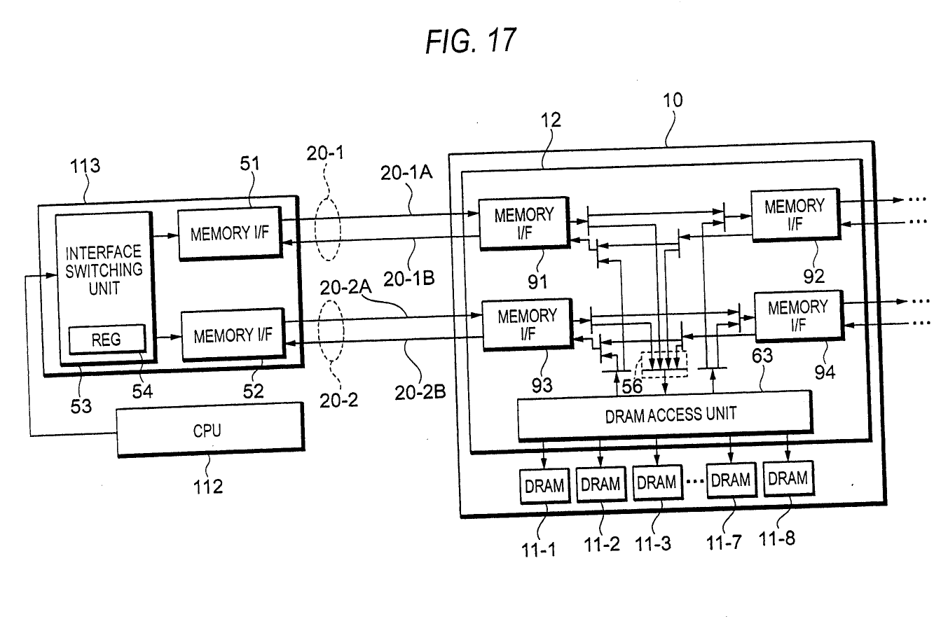

FIG. 17 illustrates the detailed structure of the memory 114 shown in FIG. 16. The buffer unit 12 of the FB-DIMM 10 comprises memory interface units 91, 92, 93, 94 which can perform a memory access from the memory controller 113 through the serial interface signal lines 20-1, 20-2 from the same direction (one direction) or different directions (bi-direction). The buffer unit 12 comprises an exclusive control unit 56 for allowing any one memory access, with respect to the memory accesses which are actually simultaneously performed from the same direction or from different directions through the serial interface signal lines 20-1, 20-2, that is, the memory accesses which are actually simultaneously performed in a bi-direction of the memory interface units 91, 93, the memory accesses which are actually simultaneously performed in a bi-direction of the memory interface units 92, 94, the memory accesses which are actually simultaneously performed in a bi-direction of the memory interface units 91, 94, or the memory accesses which are actually simultaneously performed in a bi-direction of the memory interface units 92, 93.

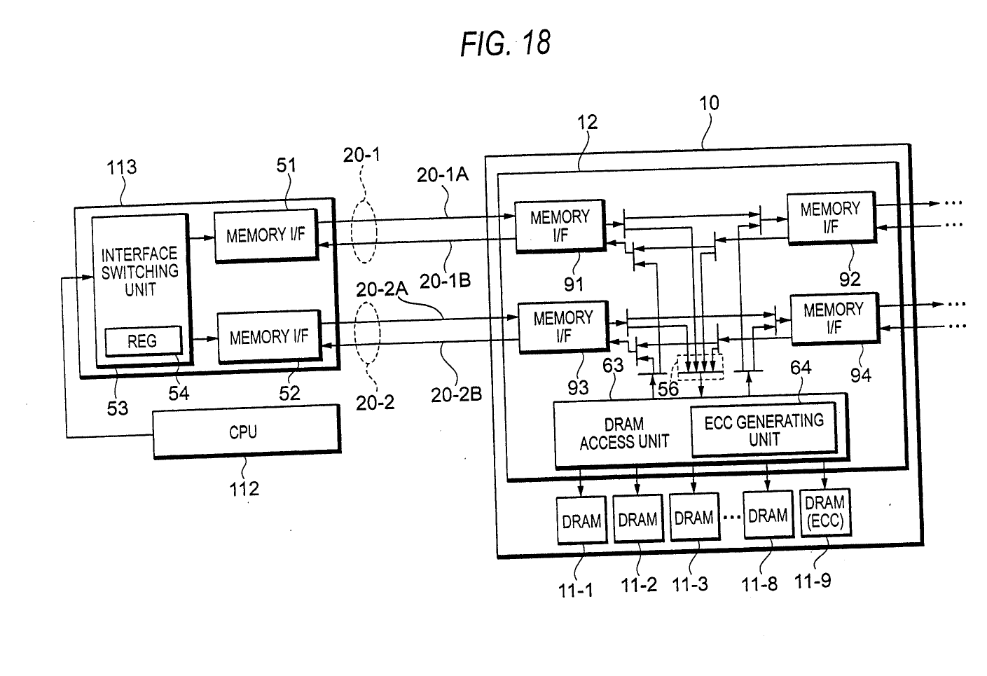

The interface switching unit 53 of the memory controller 113 selects any one of the memory interface units 51 and 52 to be used for the memory access according to the set content in the initial set register 54, when receiving a memory access request from the CPU 112. The initial set register 54 is set with information for which the memory controller 113 between the duplicated memory controllers 113 has an access right, as well as the information of the memory interface unit 51 or 52, which is generally used after performing a memory access. In the case in which the information for which the memory controller 113 has an access right is not set, the two duplicated memory controllers 113 may communicate with each other and determine which memory controller 113 has the access right. The process of switching the serial interface signal line 20-1, 20-2 used for the memory access is equal to the process of FIG. 24. FIG. 18 illustrates the structure of the memory 114 in which the ECC function is applied to the FB-DIMM 10, in addition to the structure of FIG. 17.

### Switching Function

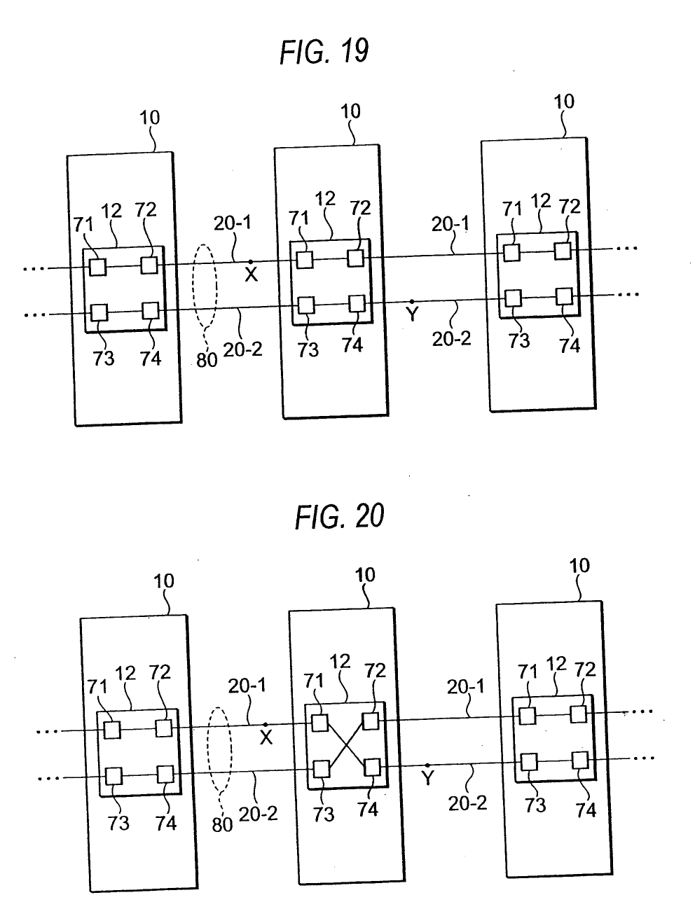

FIGS. 19 and 20 illustrate the FB-DIMM 10, which is constructed such that the path between the memory interface units 71-74 connected to the serial interface signal line 80 can be switched. This structure corresponds to the variation of the duplication of the interface signal line shown in FIGS. 13-18, and the memory interface units 71-74 can perform a memory access from the bi-direction of the serial interface signal lines 20-1, 20-2. For example, in the case of connecting the memory interface units 71, 72 and the memory interface units 73, 74, respectively, as shown in FIG. 19, when an obstacle is generated at the point X on the serial interface signal line 20-1 and the point Y on the serial interface signal line 20-2, any serial interface units 20-1, 20-2 can not perform a memory access to the centric FB-DIMM 10. Accordingly, as shown in FIG. 20, by connecting the structure such that the memory interface unit 71 is switchable to the memory interface unit 74, which is an access point, or the memory interface unit 73 is switchable to the memory interface unit 72, which is an access point, the memory access to the FB-DIMM 10 can be performed through the path of the serial interface signal line 20-2→memory interface unit 73→memory interface unit 72→serial interface signal unit 20-1 or the reverse path thereof.

### Duplication of the File Level

Here, FIG. 2 will be referred to. In a pair of the channel control units CHN1-2 (110) which make up the cluster, a duplication of the data is performed such that the data written to the memory 114 of one channel control unit CHN1 (110) is written to the memory 114 of the other channel control unit CHN2 (110). By this structure, although any obstacle is generated in one channel control unit CHN1 (110), the process which has been performed by the channel control unit CHN1 (110) until that time is continuously performed by the other channel control unit CHN2 (110). The duplicated data is, for example, the file data to which the file access was requested from the information-processing device 200.

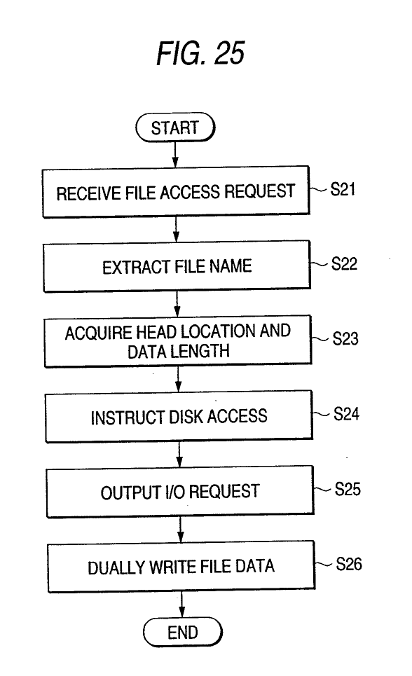

FIG. 25 is a flowchart illustrating a process of dually writing the file data. Here, the example of duplicating the file data by writing the file data to the memory 114 of the channel control unit CHN2 (110) as well as its own memory 114 by the channel control unit CHN1 (110) which receives the file access request will be explained. The network interface unit 111 of the channel control unit CHN1 (110) receives the file access request (data access command) from the information-processing devices 1 and 2 (200) (S21). The file access request includes a file name, the access kind of read or write, the write data, the header information of the LAN communication protocol, and the like. The CPU 112 extracts the file name from the file access request received through the network interface unit 111 (S22). Next, the CPU 112 acquires the top location of the file data and the data length (capacity) with reference to the metadata stored in the memory 114 (S23). Then, the CPU 112 instructs the disk access to the input/output control unit 115 (S24). The input/output control unit 115 outputs the I/O request (command) for the file access request from the information-processing device 200, depending on the stored location of the file and the data length (S25). This I/O request is written to the shared memory 120. Thereby, the data access for the storage device 300 is performed.

When receiving a file access request of “write” from the information-processing device 1 (200), the channel control unit CHN1 (110) writes the file data to the memory 114 of the channel control unit CHN1 (110) and then writes the file data to the memory 114 of the channel control unit CHN2 (110) (S26). When a duplication of the file data is performed, the channel control unit CHN1 (110) writes the corresponding file data to the storage device 300. At this time, the channel control unit CHN1 (110) may write the corresponding file data to the storage device 300 after writing it to the cache memory 130, or it may directly write the corresponding file data to the storage device 300 without writing it to the cache memory 130. Here, in the case of writing the file data to the storage device 300 after writing it to the cache memory 130, the file data written to the cache memory 130 may be invalidated. Here, invalidation means allowing a dual storage of the data.

The channel control unit CHN1 (110) determines whether or not the file data to be read exists in the memory 114 of the channel control unit CHN1 (110), when receiving a file access request of “read” from the information-processing device 1 (200). In a case where the corresponding file data exists in the memory 114, the channel control unit CHN1 (110) transmits the file data read from the memory 114 to the information-processing device 1 (200). In a case where the file data to be read does not exist in the memory 114, the channel control unit CHN1 (110) determines whether the corresponding file data exists in the cache memory 130; and, if the corresponding file data exists in the cache memory 130, the channel control unit CHN1 (110) reads the corresponding file data from the cache memory 130 and transmits it to the information-processing device 1 (200). In a case where the corresponding file data does not exist in the cache memory 130, the channel control unit CHN1 (110) accesses the storage device 300, reads the corresponding file data therefrom, and transmits it to the information-processing device 1 (200). The channel control unit CHN1 (110) writes the file data acquired from the storage device 300 or the cache memory 130 to the memory 114 of the channel control unit CHN2 (110) (S26).

As an example of the process of dually writing the file data, there are a method A in which the file data temporarily stored in the memory 114 of the channel control unit CHN1 (110) is dually written to each of the cache memories 130-1, 130-2 and is not stored in the memory 114 of the channel control unit CHN1 (110), and a method B in which the data written to the memory 114 of the channel control unit CHN1 (110) is also written to the memory 114 of the channel control unit CHN2 (110) and is not dually written to the cache memories 130-1, 130-2. Also, in the case of employing the method B as the process of dually writing the file data, the number of wires in the connection unit 150 can be reduced, and, thus, the connection unit 150 can be miniaturized. Further, by dually writing the data to the memories 114 of the channel control units CHN1 and CHN2 (110), the response time for access from the information-processing device 1 (200) can be shortened.

In addition, in a case where the channel control unit CHN1 (110) receives a file access request of “write” from the information-processing device 1 (200), the file data (the write data) written to the storage device 300 may be dually written to the cache memories 130-1, 130-2, similar to the above-mentioned method A, or it may be dually written to the memories 114 of the channel control units CHN1 and CHN2 (110), similar to the above-mentioned method B. Also, in a case where the channel control unit CHN1 (110) receives a file access request of “read” from the information-processing device 1 (200), the file data (the read data) read from the cache memory 130 or the storage device 300 may be dually written to the cache memories 130-1, 130-2, similar to the above-mentioned method A, or it may be dually written to the memories 114 of the channel control units CHN1 and CHN2 (110), similar to the above-mentioned method B.

Also, after writing the data to the storage device 300, the data may be written to the cache memory 130 and then to the storage device 300, or the data may be directly written to the storage device 300 without being written to the cache memory 130. By storing data whose access frequency is high to the cache memory 130, the processing speed of the channel control unit 110 can be improved. In a case where the data is not written to the cache memory 130, the storage resource of the storage device control apparatus 100 has a small capacity.

### The Other Embodiments

The memory 114, in which the memory controller 113 and the serial interface are duplicated, is not limited to a temporary storage device of the CPU 112, and all of the temporary storage devices of the disk control apparatus 100 (for example, the shared memory 120, the cache memory 130, the memories 143 of the disk control units 140) can be applied.

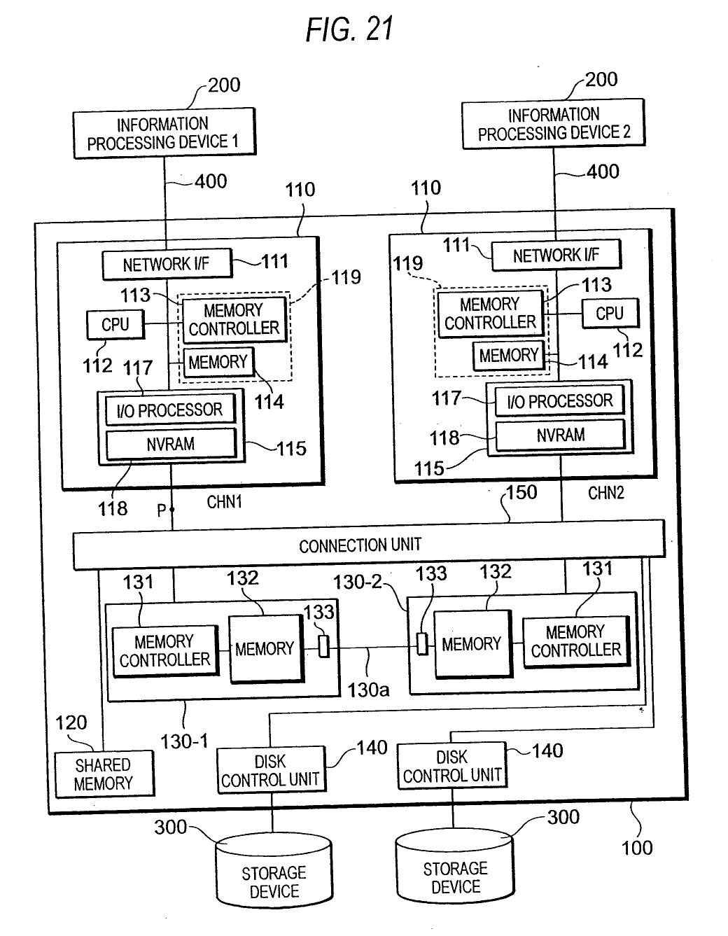

FIG. 21 illustrates an example of forming a the cluster by use of a pair of cache memories 130-1, 130-2 in the storage system 600 shown in FIG. 1. Each of the cache memories 130-1, 130-2 comprises a memory controller (a cache memory controller) 131, a memory 132, and a converting circuit 133. The memory controller 131 is a circuit for controlling memory access from the channel control unit 110 or the disk control unit 140 to the memory 132. The memory 132 is a memory device using the FB-DIMM 10 as a cache memory module. In the structure of connecting the memory controller 131, the memory 132 and the converting circuit 133 in the cache memories 130-1, 130-2, a duplication of the serial interface signal line is performed, as shown in FIG. 16. In other words, the memory 132 of the cache memory 130-1 can be accessed from the memory controller 131 of the cache memory 130-2, as well as from the memory controller 131 of the cache memory 130-1. Similarly, the memory 132 of the cache memory 130-2 can be accessed from the memory controller 131 of the cache memory 130-1, as well as from the memory controller 131 of the cache memory 130-2. Of course, as the duplication of the serial interface between the memory controller 131 and the memory 132 in the cache memories 130-1, 130-2, the above-mentioned (1) duplication of the write data (FIGS. 6 to 9) or (2) duplication of the access path (FIGS. 10 to 12) can be employed.

The cache memories 130-1, 130-2 which make up the cluster can communicate with each other through the signal line 130a and can share data. In the case of sending the data between the cache memories 130-1, 130-2, since the distance therebetween is long, a skew may be generated in the cluster distribution type. Accordingly, in the present embodiment, the clock extracting type is employed in the communication between the cache memories 130-1, 130-2. More specifically, since memory 132 employs a clock distribution, the clock distribution type is switched to the clock extracting type in the interface between the cache memories 130-1, 130-2. The data signal transmitted from the memory controller 131 to the memory 132 is 8B/10B-encoded and is embedded with a clock signal. The converting circuit 133 extracts the embedded clock signal by 10B/8B-converting (decoding) the data signal. The converting circuits 133 included in the cache memories 130-1, 130-2 are connected to each other through the signal line 130a. The cache memories 130-1, 130-2 can communicate data with each other through the signal line 130a. For example, the memory controller 131 of the cache memory 130-1 can perform a memory access to the memory 132 of the cache memory 130-2. Besides, the cache memories 130-1, 130-2 perform a hard bit communication through the signal line 130a, and, thus, the obstacle of the concerned party can be detected.

In a pair of cache memories 130-1, 130-2, a duplication of data is performed such that the data written to one cache memory 130-1 is also written to the other cache memory 130-2. By this structure, although an obstacle may be generated in one cache memory 130-1, the storage system 600 can continuously perform the process, which has been performed until that time, by using the data stored in the cache memory 130-2. The data duplicated in the cache memories 130-1, 130-2 is, for example, block data written to the storage device 300.

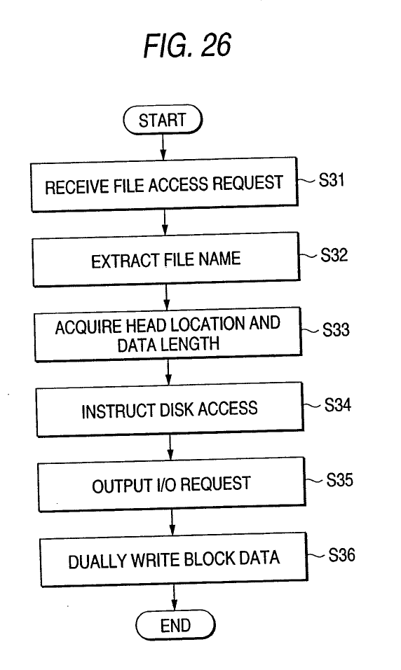

FIG. 26 is a flowchart illustrating the process of dually writing block data. Here, an example, in which the channel control unit CHN1 (110) which has received the file access request writes the block data to the cache memories 130-1, 130-2, will be explained. The network interface unit 111 of the channel control unit CHN1 (110) receives the file access request (the data access command) from the information-processing devices 1-2 (200) (S31). The file access request includes the file name, the access kind of the read or write operation, the write data, the header information of the LAN communication protocol, and the like. The CPU 112 extracts the file name from the file access request received through the network interface unit 111 (S32). Next, the CPU 112 acquires the top location of the file data and the data length (capacity) with reference to the metadata stored in the memory 114 (S33). Then, the CPU 112 instructs a disk access to the input/output control unit 115 (S34). The input/output control 115 outputs the I/O request (command) for the file access request from the information-processing devices 1-2 (200), depending on the stored location of the file and the data length (S35). This I/O request is written to the shared memory 120. Thereby, the data access for the storage device 300 is performed. When receiving a file access request of “write” from the information-processing devices 1-2 (200), the input/output control unit 115 writes the data (the block data) received from the information-processing devices 1-2 (200) to the cache memories 130-1, 130-2; and, when receiving a file access request of “read” from the information-processing devices 1-2 (200), the disk control unit 140 reads the data from the storage device 300 and writes the read data (the block data) to the cache memories 130-1, 130-2 (S36).

As the process of dually writing the block data, there is a method in which the channel control unit CHN1 (110) writes the block data to both cache memories 130-1, 130-2. Alternatively, there is a method in which the channel control unit CHN1 (110) writes a write command of the block data to the shared memory 120 after writing the block data to only the cache memory 130-1, and then the memory controller 131 or the disk control unit 140, reading the command, writes the block data to the cache memory 130-2. In addition, there is a method in which the CPU for writing the block data is mounted on the cache memories 130-1, 130-2, the CPU reads the write command which the channel control unit CHN1 (110) writes to the shared memory 120, and the CPU writes the corresponding block data to the cache memory 130-2. Also, there is a method in which the disk control unit 140 writes a write command for the cache memory 130-2 to the shared memory 120, and the memory controller 131 (or the CPU for writing the block data) or the channel control unit CHN1 (110), reading the write command, writes the corresponding block data to the cache memory 130-2. By this structure, the number of wires in the connection unit 150 can be reduced, and the connection unit 150 can be miniaturized. The more the number of channel control units CHN, CHF, CHA (110) is increased, the more the effect is increased.

Also, in accessing any one of the cache memories 130-1, 130-2 by the channel control unit CHN1-CHN4 (110), the channel control unit CHN1-CHN4 (110) may be dynamically switched according to the access frequency for the cache memories 130-1, 130-2, or, alternatively, it may be accessed for the cache memories. Alternatively, one cache memory is set to an operation system, and the other cache memory is set to a waiting system and the cache memory which is the operating system is generally accessed. Thereby, in the case in which an obstacle is generated in one cache memory, a memory access from the other cache memory is performed.

In the case in which an obstacle is generated in the cache memory 130-1, the data of the cache memory 130-2 is preferably written to the storage device 300 by the disk control unit 140. By storing the same data as that stored in the cache memory 130-2 to the storage device 300, a duplication of the data can be performed, and, thus, the reliability of the storage system 600 can be ensured.

According to the structure shown in FIG. 21, in the case that the obstacle is generated between the channel control unit CHN1 (110) and the connection unit 150 (for example, the point P in the FIG. 21), the data can be duplicated between the cache memory 130-1 and the cache memory 130-2 through the connection unit 150 and the signal line 130a.

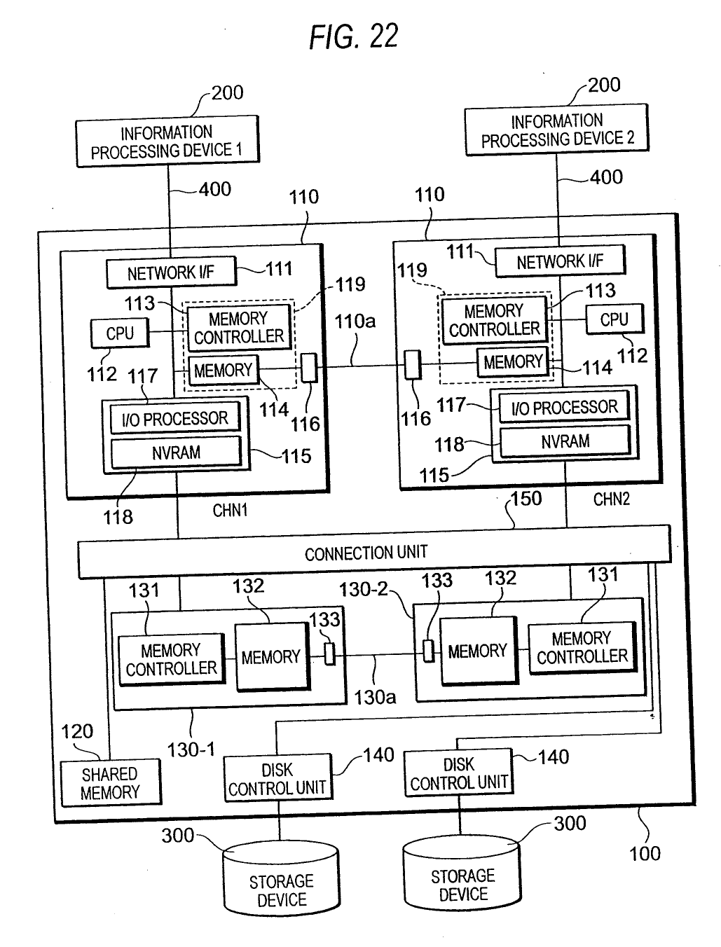

FIG. 22 illustrates an example in which a cluster is formed by connecting the channel control units CHN1 and CHN2 (110) and an example in which a cluster is formed by connecting the cache memories 130-1, 130-2. In this structure, by storing the file data to the memory 114 of the channel control unit CHN1 and the memory 114 of the channel control unit CHN2, a duplication of the data can be performed. Alternately, by storing the block data to the cache memory 130-1 and the cache memory 130-2, a duplication of the block data can be performed. By this structure, the memory capacity of the cache memories 130-1, 130-2 can largely ensured.

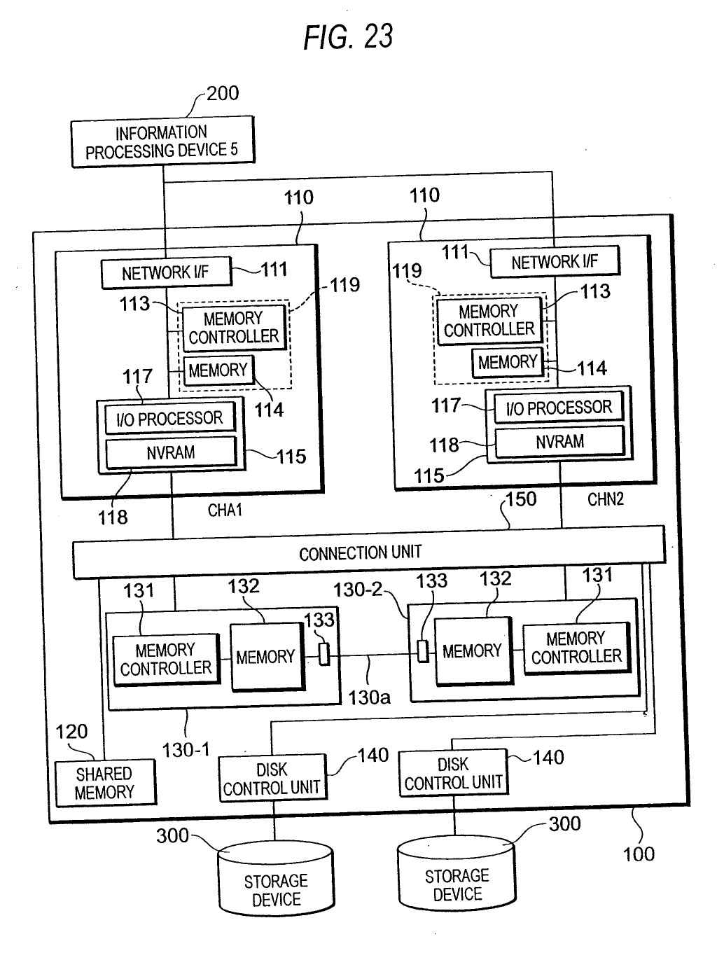

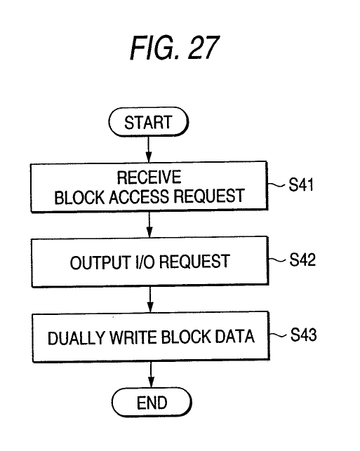

FIG. 23 illustrates an example in which a cluster is formed by a pair of cache memories 130-1, 130-2 in the storage device control apparatus 100 comprising the channel control units CHN1-2 (110). In this structure, the process of dually writing block data to the cache memories 130-1 and 130-2 is performed as follows. FIG. 27 is a flowchart illustrating the process of dually writing the block data. The network interface unit 111 of the channel control unit CHA1 (110) receives a block access request from the information processing device 5 (200) (S41). Then, the input/output control unit 115 outputs an I/O request (command) for the block file access request (S42). This I/O request is written to the shared memory 120. Thereby, the data access for the storage device 300 is performed. When receiving a block file access request of “write” from the information processing device 5 (200), the input/output control unit 115 writes the data (the block data) received from the information processing device 5 (200) to the cache memories 130-1, 130-2; and, when receiving a block file access request of “read” from the information-processing device 5 (200), the disk control unit 140, reading the data from the storage device 300, writes the read data (the block data) to the cache memories 130-1, 130-2 (S43).

Although various embodiments of the present invention have been described, the present invention is not limited to this. The present invention is intended to cover various modifications and equivalent arrangements included within the spirit and scope of the invention as hereafter claimed. For example, the memory system 119 mentioned in the present embodiment is not limited to the storage device control apparatus 100, and a computer apparatus having high reliability can be applied. Also, the memory system 119 comprises the above-mentioned serial interface, thereby high reliability can be ensured and the circuit components can be easily mounted.

According to the present invention, the serial interface between the memory controller and the memory modules can be duplicated, thereby increasing the reliability of the storage device control apparatus.

What is claimed is:

1. A storage device control apparatus comprising a plurality of channel control units for outputting an input/output request for a storage device in response to a data input/output request in a file unit from an information processing device, the plurality of channel control units being clustered, wherein each of the plurality of channel control units includes:
a central processing unit for receiving the data input/output request in the file unit;
an I/O processor for outputting the input/output request corresponding to the data input/output request in the file unit in response to an instruction from the CPU; and
a memory system for temporarily storing information required for a file access process of the CPU and having first and second systematic memory module groups, each of which is composed of a plurality of memory modules, a memory controller for controlling memory access to the memory modules belonging to each of the first systematic and second systematic memory module groups, a control circuit for controlling switching of a memory access path from the memory controller to each of the memory modules, and a converting circuit connected via a signal line to a converting circuit located in one of the other channel control units, and a command, an address and data being serially transmitted from the memory controller to each of the memory modules,
wherein each of the memory modules has a plurality of memory elements and a plurality of buffer units,
wherein each of the buffer units receives and interprets the command serially transmitted from the memory controller, controls the memory access to each of the memory elements from the memory controller, and
simultaneously converts the serially transmitted data into parallel data and transmits the converted data to each of the memory elements,
wherein the memory controller and each of the memory modules are connected to each other by a serial interface such that a first access path for performing memory access from the memory controller to the memory module belonging to the first systematic memory module group and a second access path for performing memory access from the memory controller to the memory module belonging to the second systematic memory module group are different from each other,
wherein the memory controller writes a copy of the data stored in the first systematic memory module through the first access path to the second systematic memory module through the second access path when performing write access from the memory controller to the first systematic memory module,
wherein each of the memory systems stores a copy of the data stored in one of the other memory systems, and
wherein when the memory controller detects failure in one of the other memory systems, the memory system performs memory access to the memory modules belonging to its own systematic memory module groups.

2. The storage device control apparatus according to claim 1, comprising a plurality of cache memories for primarily storing block data read front/written to a storage device, in response to a data input/output request from an information processing device,
wherein each of the cache memories includes first and second systematic cache memory module groups, each of which is composed of a plurality of cache memory modules, a cache memory controller for controlling memory access to the cache memory modules belonging to each of the first and second systematic cache memory module groups, and a control circuit for controlling switching of a memory access path from the memory controller to each of the memory modules, and a command, an address and data being serially transmitted from the cache memory controller to each of the cache memory modules,
wherein each of the cache memory modules has a plurality of memory elements and a plurality of buffer units,
wherein each of the buffer units receives and interprets the command serially transmitted from the cache memory controller, controls the memory access to each of the serially transmitted data into parallel data and transmits them to each of the memory elements,
wherein the cache memory controller and the cache memory are connected to each other by a serial interface, so that a first access path for performing the memory access from the cache memory controller to the memory module belonging to the first systematic cache memory module group and a second access path for performing the memory access from the memory controller to the memory module belonging to the second systematic cache memory module group are different from each other, and
wherein the control circuit writes a copy of the data stored in the first systematic cache memory module through the first access path to the second systematic cache memory module through the second access path when performing a write access from the cache memory controller to the first systematic cache memory module.

3. The storage device control apparatus according to claim 1, comprising a plurality of cache memories for primarily storing block data read from/written to a storage device in response to a data input/output request from an information processing device, the plurality of cache memories being clustered,
wherein each of the cache memories includes first systematic and second systematic cache memory-module groups, each composed of a plurality of cache memory modules, a cache memory controller for controlling memory access to the cache memory modules belonging to each of the first systematic and second systematic cache memory-module groups, a control circuit for controlling switching of a memory access path from the memory controller to each of the memory modules, and a converting circuit connected via a signal line to the converting circuit located in one of the other cache memories, and a command, an address and data are serially transmitted from the cache memory controller to each of the cache memory modules,
wherein each of the cache memory modules has a plurality of memory elements and a plurality of buffer units,
wherein each of the buffer units receives and interprets the command transmitted from the cache memory controller, controls the memory access to each of the serially transmitted data into parallel data and transmits them to each of the memory elements,
wherein the cache memory controller and the cache memory are connected to each other by a serial interface so that a first access path for performing the memory access from the cache memory controller to the memory module belonging to the first systematic cache memory module group and a second access path for performing the memory access from the memory controller to the memory module belonging to the second systematic cache memory module group are different from each other, and
wherein the control circuit writes a copy of the data stored in the first systematic cache memory module through the first access path to the second systematic cache memory module through the second access path when performing a write access from the cache memory controller to the first systematic cache memory module,
wherein each of the plurality of cache memories stores a copy of the data stored in one of the other cache memories,
wherein when the memory controller detects failure in one of the other cache memories, the cache memory performs memory access to the cache memory modules belonging to its own systematic cache memory-module groups.

4. The storage device control apparatus according to claim 1, wherein each of the buffer units comprises an error correcting code (ECC) generating unit for generating an ECC depending on data written in the memory element.

5. The storage device control apparatus according to claim 1, wherein the memory controller is formed in the CPU.

6. A storage device control apparatus comprising a plurality of cache memories for primarily storing block data read from/written to a storage device in response to a data input/output request from an information processing device,
wherein each of the cache memories includes first systematic and second systematic cache memory-module groups, each of which is composed of a plurality of cache memory modules, a cache memory controller for controlling memory access to the cache memory modules belonging to each of the first systematic and second systematic cache memory-module groups, a control circuit for controlling switching of a memory access path from the memory controller to each of the memory modules, and a converting circuit connected via a signal line to a converting unit located in the one of the other cache memory, and a command, an address and data are serially transmitted from the cache memory controller to each of the cache memory modules,
wherein each of the cache memory modules has a plurality of memory elements and a plurality of buffer units,
wherein each of the buffer units receives and interprets the command serially transmitted from the cache memory controller, controls the memory access to each of the serially transmitted data into parallel data and transmits them to each of the memory elements,
wherein the cache memory controller and the cache memory are connected to each other by a serial interface so that a first access path for performing the memory access from the cache memory controller to the memory module belonging to the first systematic cache memory module group and a second access path for performing the memory access from the memory controller to the memory module belonging to the second systematic cache memory module group are different from each other, and
wherein the control circuit writes a copy of the data stored in the first systematic cache memory module through the first access path to the second systematic cache memory module through the second access path when performing a write access from the cache memory controller to the first systematic cache memory module,
wherein each of the plurality cache memories stores a copy of the data stored in one of the other cache memories, and
wherein when the memory controller detects failure in one of the other cache memories, the cache memory performs memory access to the cache memory modules belonging to their own systematic memory module groups.

7. The storage device control apparatus according to claim 6, comprising a channel control unit for outputting an input/output (I/O) request for a storage device in response to a data input/output request in a file unit from an information-processing device,
wherein the channel control unit includes:
a central processing unit (CPU) for receiving the data input/output request in the file unit;
an I/O processor for outputting the I/O request corresponding to the data input/output request in the file unit in response to an instruction from the CPU; and
a memory system for temporarily storing information required for a file access process of the CPU and having first systematic and second systematic memory module groups each composed of a plurality of memory modules, a memory controller for controlling memory access to the memory modules belonging to each of the first systematic and second systematic memory-module groups, and a control circuit for controlling the switching of a memory access path from the memory controller to each of the memory modules, and a command an address and data being serially transmitted from the memory controller to each of the memory modules,
wherein each of the memory modules has a plurality of memory elements and a plurality of buffer units,
wherein each of the buffer units receives and interprets the command transmitted from the memory controller, controls the memory access to each of the memory elements from the memory controller, and simultaneously converts the serially transmitted data into parallel data and transmits them to each of the memory elements,
wherein the memory controller and each of the memory modules are connected to each other by a serial interface so that a first access path for performing the memory access from the memory controller to the memory module belonging to the first systematic memory-module group and a second access path for performing the memory access from the memory controller to the memory module belonging to the second systematic memory-module group are different from each other, and
wherein the memory controller writes a copy of the data stored in a first memory module through a first access path to a second memory module through a second access path when performing a write access from the memory controller to the first memory module.

8. The storage device control apparatus according to claim 6, wherein each the buffer units comprises an error correcting code (ECC) generating unit for generating an ECC depending on data written on the memory elements.
